(19) United States
(12) Patent Application Publication
(10) Pub. No.: US 2024/0193708 A1
(43) Pub. Date: Jun. 13, 2024

(54) METHOD, APPARATUS, AND SYSTEM FOR DETERMINING OBJECT UTILITY DATA FOR PERSONALIZING SERVICES FOR SPACE UTILIZATION

(71) Applicant: HERE Global B.V., Eindhoven (NL)

(72) Inventors: Jerome BEAUREPAIRE, Nantes (FR); Nicolas NEUBAUER, Berlin (DE); Jens UNGER, Berlin (DE)

(21) Appl. No.: 18/077,083

(22) Filed: Dec. 7, 2022

(51) Int. Cl. G06Q 50/06; G06Q 30/0601

(52) U.S. Cl. CPC G06Q 50/06; G06Q 30/0633

(57) ABSTRACT

An approach is provided for determining object utility for personalizing service for space utilization. The approach, for example, involves using a sensor to capture sensor data of an environment including an object over a period of time. The approach also involves processing the sensor data to track one or more interactions between at least one user and the object over the period of time. The approach further involves determining a utility value of the object based on the one or more interactions. The approach further involves providing the utility value as an output. In one example embodiment, the approach further involves determining a service, an action, or a combination thereof to apply to the object based on the utility value.

### BACKGROUND

Location-based service providers (e.g., mapping and navigation providers) are continually challenged to provide compelling services and applications. One area of development relates to understanding how objects that are acquired over time can affect a user's space and environment. However, the dynamic nature of how objects are used and where they are placed makes automatically detecting and assessing the objects technically challenging.

### SOME EXAMPLE EMBODIMENTS

Therefore, there is a need for automatically determining object utility data and then personalizing services for utilizing the space or environment (e.g., a room or home) where the objects are placed or otherwise stored.

According to one embodiment, a method comprises using a sensor to capture sensor data of an environment including an object over a period of time. The method also comprises processing the sensor data to track one or more interactions between at least one user and the object over the period of time. The method further comprises determining a utility value of the object based on the one or more interactions. The method further comprises providing the utility value as an output. In one example embodiment, the method further comprises determining a service, an action, or a combination thereof to apply to the object based on the utility value.

According to another embodiment, an apparatus comprises at least one processor, and at least one memory including computer program code for one or more computer programs, the at least one memory and the computer program code configured to, with the at least one processor, cause, at least in part, the apparatus to use a sensor to capture sensor data of an environment including an object over a period of time. The apparatus is also caused to process the sensor data to track one or more interactions between at least one user and the object over the period of time. The apparatus is further caused to determine a utility value of the object based on the one or more interactions. The apparatus is further caused to provide the utility value as an output. In one example embodiment, the apparatus is further caused to determine a service, an action, or a combination thereof to apply to the object based on the utility value.

According to another embodiment, a non-transitory computer-readable storage medium carries one or more sequences of one or more instructions which, when executed by one or more processors, cause, at least in part, an apparatus to use a sensor to capture sensor data of an environment including an object over a period of time. The apparatus is also caused to process the sensor data to track one or more interactions between at least one user and the object over the period of time. The apparatus is further caused to determine a utility value of the object based on the one or more interactions. The apparatus is further caused to provide the utility value as an output. In one example embodiment, the apparatus is further caused to determine a service, an action, or a combination thereof to apply to the object based on the utility value.

In addition, for various example embodiments described herein, the following is applicable: a computer program product may be provided. For example, a computer program product comprising instructions which, when the program is executed by a computer, cause the computer to perform any one or any combination of methods (or processes) disclosed.

According to another embodiment, an apparatus comprises means for using a sensor to capture sensor data of an environment including an object over a period of time. The apparatus also comprises means for processing the sensor data to track one or more interactions between at least one user and the object over the period of time. The apparatus further comprises means for determining a utility value of the object based on the one or more interactions. The apparatus further comprises means for providing the utility value as an output. In one example embodiment, the apparatus further comprises means for determining a service, an action, or a combination thereof to apply to the object based on the utility value.

In addition, for various example embodiments of the invention, the following is applicable: a method comprising facilitating a processing of and/or processing (1) data and/or (2) information and/or (3) at least one signal, the (1) data and/or (2) information and/or (3) at least one signal based, at least in part, on (or derived at least in part from) any one or any combination of methods (or processes) disclosed in this application as relevant to any embodiment of the invention.

For various example embodiments of the invention, the following is also applicable: a method comprising facilitating access to at least one interface configured to allow access to at least one service, the at least one service configured to perform any one or any combination of network or service provider methods (or processes) disclosed in this application.

For various example embodiments of the invention, the following is also applicable: a method comprising facilitating creating and/or facilitating modifying (1) at least one device user interface element and/or (2) at least one device user interface functionality, the (1) at least one device user interface element and/or (2) at least one device user interface functionality based, at least in part, on data and/or information resulting from one or any combination of methods or processes disclosed in this application as relevant to any embodiment of the invention, and/or at least one signal resulting from one or any combination of methods (or processes) disclosed in this application as relevant to any embodiment of the invention.

For various example embodiments of the invention, the following is also applicable: a method comprising creating and/or modifying (1) at least one device user interface element and/or (2) at least one device user interface functionality, the (1) at least one device user interface element and/or (2) at least one device user interface functionality based at least in part on data and/or information resulting from one or any combination of methods (or processes) disclosed in this application as relevant to any embodiment of the invention, and/or at least one signal resulting from one or any combination of methods (or processes) disclosed in this application as relevant to any embodiment of the invention.

In various example embodiments, the methods (or processes) can be accomplished on the service provider side or on the mobile device side or in any shared way between service provider and mobile device with actions being performed on both sides.

For various example embodiments, the following is applicable: An apparatus comprising means for performing a method of the claims.

Still other aspects, features, and advantages of the invention are readily apparent from the following detailed description, simply by illustrating a number of particular embodiments and implementations, including the best mode contemplated for carrying out the invention. The invention is also capable of other and different embodiments, and its several details can be modified in various obvious respects, all without departing from the spirit and scope of the invention. Accordingly, the drawings and description are to be regarded as illustrative in nature, and not as restrictive.

### BRIEF DESCRIPTION OF THE DRAWINGS

The embodiments of the invention are illustrated by way of example, and not by way of limitation, in the figures of the accompanying drawings:

FIG. 1 is a diagram of a system capable of determining an object's utility value for personalizing space utilization services, according to one example embodiment;

FIG. 2 is a diagram of the components of mapping platform capable of determining an object's utility value for personalizing space utilization services, according to one example embodiment;

FIG. 3 is a flowchart of a process for determining an object's utility value for personalizing space utilization services, according to one example embodiment;

FIG. 4 is a diagram illustrating a data pipeline for determining an object utility value, according to one example embodiment;

FIG. 5 is a diagram illustrating an example user interface for presenting an object utility value, according to one example embodiment;

FIG. 6 is a flowchart of a process for associating an object with a spatial budget, according to one example embodiment;

FIGS. 7A-7C are diagrams illustrating example cost factors for computing a spatial cost of an object, according to various example embodiments;

FIG. 8 is a diagram illustrating an example representation of a spatial cost of an object, according to one example embodiment;

FIGS. 9A-9D are diagrams illustrating example factors for computing a spatial budget of an object, according to various example embodiments;

FIG. 10 is a diagram illustrating example plane surfaces for object placement, according to one example embodiment;

FIG. 11 is a diagram illustrating an example user interface for presenting object spatial cost data, according to one example embodiment;

FIG. 12 is a diagram of a geographic database, according to one embodiment;

FIG. 13 is a diagram of hardware that can be used to implement an embodiment;

FIG. 14 is a diagram of a chip set that can be used to implement an embodiment; and

FIG. 15 is a diagram of a mobile terminal (e.g., handset or vehicle or part thereof) that can be used to implement an embodiment.

### DESCRIPTION OF SOME EMBODIMENTS

Examples of a method, apparatus, and computer program for determining object utility data for personalizing services for space utilization are disclosed. In the following description, for the purposes of explanation, numerous specific details are set forth in order to provide a thorough understanding of the embodiments of the invention. It is apparent, however, to one skilled in the art that the embodiments of the invention may be practiced without these specific details or with an equivalent arrangement. In other instances, well-known structures and devices are shown in block diagram form in order to avoid unnecessarily obscuring the embodiments of the invention.

Reference in this specification to “one embodiment” or “an embodiment” means that a particular feature, structure, or characteristic described in connection with the embodiment is included in at least one embodiment of the present disclosure. The appearance of the phrase “in one embodiment” in various places in the specification are not necessarily all referring to the same embodiment, nor are separate or alternative embodiments mutually exclusive of other embodiments. In addition, the embodiments described herein are provided by example, and as such, “one embodiment” can also be used synonymously as “one example embodiment.” Further, the terms “a” and “an” herein do not denote a limitation of quantity, but rather denote the presence of at least one of the referenced items. Moreover, various features are described which may be exhibited by some embodiments and not by others. Similarly, various requirements are described which may be requirements for some embodiments but not for other embodiments.

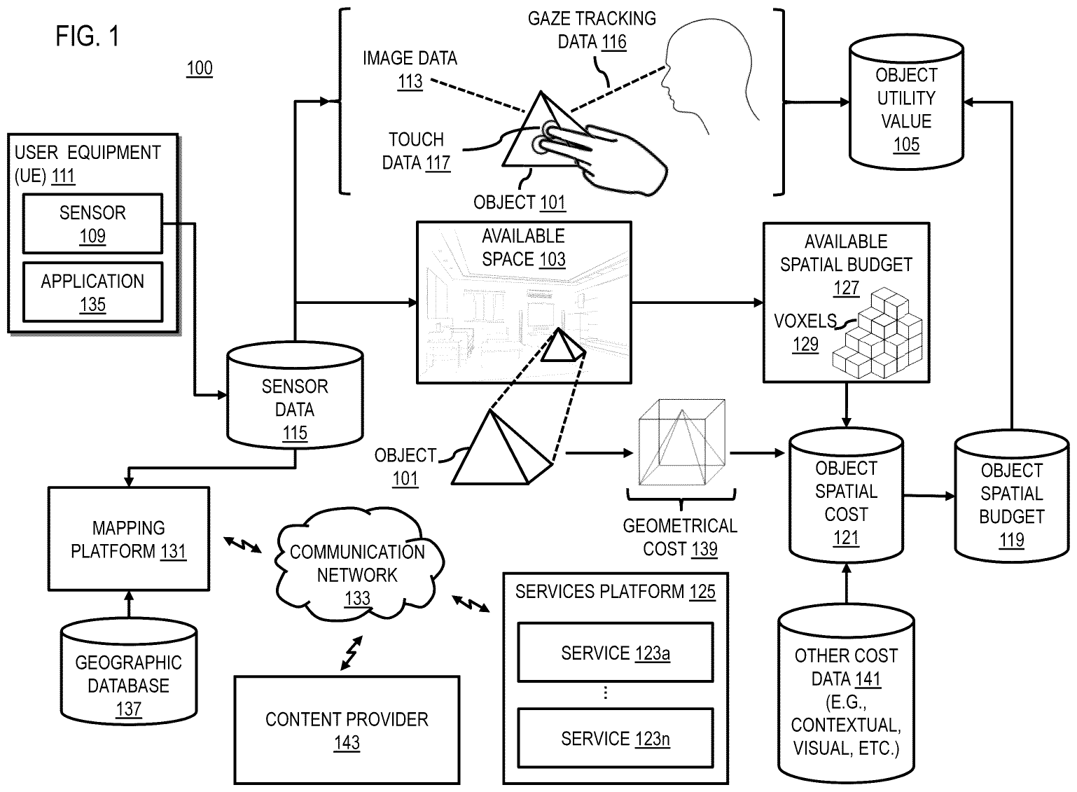

FIG. 1 is a diagram of a system capable of determining an object's utility value for personalizing space utilization services, according to one example embodiment. Many people gather objects (e.g., object 101) over time in the available space 103 in their homes or other environments (e.g., workplaces, storage units, public areas, etc.) which clutters the available space 103 over time, even if those objects 101 are not used any more. It is noted although the various example embodiments may discuss objects 101 that are in homes, it is contemplated that the embodiments are also applicable to any other place or environment such as but not limited to the examples described herein. As used herein, the term “object” refers to any tangible thing that can be placed or otherwise occupies space in a given area (e.g., the available space 103 such as but not limited to person's home, or any other designated volumetric/three-dimensional space, etc.). People generally do not realize that the space taken by objects 101 also has a “cost” associated to it (e.g., taking space or incurring an object spatial cost 121), even if the object 101 is not being much used.

To address this issue, the system 100 of FIG. 1 introduces a technical capability to track usage of objects 101 in an available space 103 (e.g., a living or working space) that allows tenants or other users identify the utility of the objects 101 (e.g., object utility value 105) in that available space 103 by integrating inputs (e.g., sensor data 107) from one or more sensors 109 of a user equipment (UE) device 111. In one embodiment, the sensor data 107 can be used to determine how a user interacts with a given object 101 (e.g., number of interactions, length of interactions, type of interaction, etc.). As used herein, the term “interacts” or “interactions” refers to when a user touches, looks at, and/or otherwise uses an object 101. For example, the sensor data 107 can include image data 113 that is processed (e.g., by a machine-learning based feature/object detector) to identify when a user interacts with an object 101. As another example, the sensor data 107 can include gaze tracking data 116 that detects when the user looks at the object 101. As another example, touch sensors on the object 101 and/or the hands of the user can be used to collect sensor data 107 (e.g., touch data 117) indicating when the object 101 has been touched or handled by the user. In yet another example, the object 101 can be a smart device or Internet of Things (IOT) device capable of reporting to the system 100 when the object 101 has been used, touched, etc. It is noted that the above types of sensors 109 and sensor data 107 are provided by way of illustration and not as limitations. It is contemplated that the sensors 109 can be type capable of detecting any form of interaction between a user and the object 101.

In one embodiment, the system 100 builds on various embodiments of methods and processes that associate objects 101 with a spatial budget (e.g., object spatial budget 119). The object spatial budget 119 relates to determining how much space (e.g., plane surfaces) is available in a home or other environment to place objects 101 and establish a list of all the objects 101 at home in order to get the full visibility of what is present and potentially “cluttering” that space 103.

In the various embodiments described herein, the system 100 goes further and determines a utility value (e.g., object utility value 105) which is related to how much a person or family interacts with one or more objects 101 in the available space 103 to help answer questions such as but not limited to the following:
Is each object 101 positioned at its right place in the available space 103 to maximize utility?
Should a given object 100 be on placed on a “premium” location in the available space 103 (e.g., a location within the available space 103 that can be reached or is visited most frequency or easily) based on its daily usage and computed object utility value 105?

In one example use case, the various embodiments described herein is about helping people benefit from “Minimalism as a service” which seeks to minimize the number of objects 101 a person places in a space while also providing for maximum utility (or usage) of the selected objects 101. This type of service matters because once people realize or are presented with the cost (e.g., object spatial cost 121 relative to the object utility value 105) associated with specific objects 101. By exposing the object utility value 105 and/or object spatial cost 121, the system 100 can be used to make people or users realize that stored objects 101, taking space in their home or other available space 103, are not neutral.

After that, realizing how much they use or interact with each object 101 can make people realize whether they really want or need to keep each object 101 in those locations of the available space 103.

With those two pieces of information, the system 100 can then make recommendations regarding specific actions and/or services (e.g., services 123a-123n—also collectively referred to as services 123—of the services platform 125 such as storage services, auction services, rental services, etc.) they should consider such as but not limited to:
Giving away unused or underutilized objects 101 via one or more services 123, e.g., thereby giving the objects 101 a second life;
Selling unused or underutilized objects 101 or an auction or marketplace service 123, e.g., thereby leading to additional revenue;
Possibly realizing that a user/couple does not need such a large home or available space 103 once the home is decluttered of unused objects 101 (e.g., if their children are older and gone from the home), e.g., thereby leading to taking a smaller house/flat with a smaller overall footprint; and
Giving people more space inside their home (or other available space 103) once the unused/unwanted objects 101 are removed.

In one embodiment, the system 100 enables users to benefit from contextually relevant services (e.g., personalized external storage facilities) and optimization suggestions by leveraging the object utility value 105 derived from how people interact with objects 101 in their home and/or other available spaces 103. For example, real estate prices keep increasing, hence people can buy less surface or space 103 than before with the same amount of money. Thus, there is an increased pressure to quantify the use of goods or objects 101 at home, offices, and/or any other available spaces. In this way, the system 100 can recommend or facilitate finding recommended solutions (e.g., relocating an object 101 to a storage service 123) for a given object 101 when its object utility value 105 is below a threshold.

To support determining object utility for personalizing services for space utilization (e.g., optimizing or recommending object position, placement, storage, etc. to maximize utility), the system 100 can quantify the spatial costs of objects 101 (e.g., object spatial cost 121) and then present the spatial cost 121 so that people realize it and can then take appropriate actions (e.g., keep, sell, give, repurpose, etc. the corresponding objects 101 via a corresponding service 123). In one embodiment, the system 100 manages an indoor space (e.g., the available space 103 of a home or other place) by determining a spatial cost 121 associated with an object 101 in the available space 103 and computing the spatial budget of the available space 103 (e.g., computed as an available spatial budget 127 represented as volumetric pixels (voxels) 129 or any other cubic/volumetric unit available for storage of objects 101). In one embodiment, the system 100 further uses the object spatial cost 121 to compute a relative cost of the object 101 with respect to the available spatial budget 127 (e.g., represented by an object spatial budget 119) and can link the object spatial budget 119 and/or object spatial costs 121 to an actual financial cost (e.g., based on the financial cost per volume of space of the available space 103).

In other words, the system 100 helps consumers declutter their homes or other spaces and live in a more sustainable way by providing contextual insights (e.g., object utility value 105, object spatial costs 121, and/or object spatial budgets 119) about the objects 101 in their homes. The system 100, for instance, enables users to quantify an object 101's impact on the available space 103 in their homes by computing the object utility value 105, spatial cost 121, and/or spatial budget 119 for object(s) 101 in their homes. In one embodiment, the system 100 can use the object utility value 105 alone or in combination with the spatial cost 121 and/or spatial budget 119 to suggest an area of or position in the available space 103 (e.g., a plane surface such as but not limited to a table, shelf, wall, etc.) where an object 101 would fit. In another embodiment, the system 101 can provide suggestions or recommendations during a purchase or acquisition of the object 101 based on the computed object spatial cost 121 and/or object spatial budget 119 and the available spatial budget 127 of the place (e.g., the available space 103) where the object 101 is to be placed.

In one embodiment, the system 100 can gather data about objects 101 within a given volumetric (e.g., three-dimensional (3D)) space (e.g., the available space 103 of a home or any other place/environment of interest). In one embodiment, the system 100 use one or more sensors 109 (e.g., a camera sensor, a light detection and ranging (LiDAR) sensor, etc.) to collect data (e.g., sensor data 107) or receive data (e.g., object specification data transmitted or reported by “smart/connected” objects 101 or from a database of object specifications) related to the objects 101 via UEs 111 (e.g., a mobile device, a smartphone, etc.) having connectivity to a mapping platform 131 via a communication network 133. In one embodiment, the UEs 111 are equipped with or otherwise have connectivity to one or more sensors 109 configured to scan an environment (e.g., the available space 103) and generate sensor data 107 (e.g., image data, LiDAR point clouds, etc.) from which the objects 101 and their properties (e.g., spatial volumes) can be detected or otherwise determined. The UEs 111 can execute one or more applications 135 (e.g., an object cataloging/indexing application, indoor mapping application, camera-based application, a navigation application, and/or any other location-based application) for detecting objects 101, detecting interactions with the objects 101, determining their object utility value 105, determining their spatial costs 121 and/or spatial budgets 119, and/or performing related functions alone or in combination with the mapping platform 131. In one instance, the system 100 can also access data or information related to the objects 101 (e.g., their locations, 3D models, etc.) stored in or accessible via a geographic database 137.

In one embodiment, the sensor data 107 can be processed to determine the object spatial cost 121 for a given object 101. The object spatial cost 121 can be any data, parameter, or metric that represents or is otherwise based on the spatial volume of the object 101. For example, the object spatial cost 121 can be based on the physical volume of the object 101. In addition or alternatively, the object spatial cost 121 can be based on a geometrical cost 139 of the object 101. The geometrical cost 139, for instance, is based on the shape of the object 101 and whether that shape would block any additional volume from being used for other objects 101. For example, a cube-shaped object and a pyramidal-shaped object with the same base dimensions and height may have different spatial volumes but would have the same geometrical cost 139 because no other object can be placed in the space around the tip of the pyramid. Thus, that space would not be available for use in placing other objects and would be counted as an additional geometrical cost 139 of the pyramidal object.

In one embodiment, the system 100 may also consider other cost data 141 to compute the object spatial cost 121 for a given object 101. Examples of other cost data 141 include but are not limited to:
Contextual costs—representing any additional volume of space that would be unusable based on placement of an object 101 (e.g., an object 101 may have a shape that would prevent stacking any other object on top of the object 101, and thus space above the object 101 would be counted as contextual cost);
Opportunity costs—representing any volume or area of a surface that would be precluded from having another object place after a given object 101 is first placed on the surface; and
Visual costs—representing costs associated with a view to other objects or features being blocked by placement of an object 101 at a given location.

In one embodiment, the object spatial cost 121 for an object 101 can be computed relative to the space 103 available for storing or placing the object. The available space 103 can be represented as an available spatial budget 127 indicating the number of designated standard voxels 129 (or other equivalent cubic/volumetric units) into which the available space 103 can be subdivided. The object spatial budget 119, for instance, can then be computed as the spatial cost 121 of the object 101 divided by the available spatial budget 127 of the home or other place in which the object 101 is placed or requested to be placed.

In one embodiment, the system 100 can provide the computed object utility value 105, object spatial cost 121, object spatial budget 119, geometrical cost 139, other cost data 141, available spatial budget 127, and/or other related data (e.g., recommendation regarding disposition of an object 101 given its utility value 105, spatial cost 121, and/or spatial budget 119) as an output. The output, for instance, can be provided to or otherwise accessed by other components of the system 100 such as but not limited to the services platform 125, one or more services 123, and/or one or more content providers 143. These components can then use the output to provide one or more functions or services associated with space utilization. As used herein, the term “space utilization” refers to any service associated with storing, placing, renting, selling, disposing, etc. of objects 101.

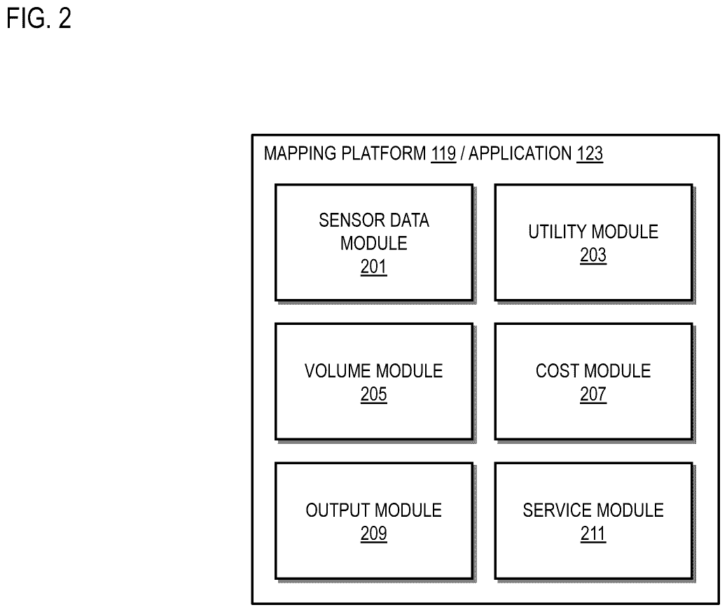

In one embodiment, the mapping platform 131 of the system 100 performs one or more functions for determining object utility for personalizing services for space utilization. FIG. 2 is a diagram of the components of mapping platform 131, according to one example embodiment. As shown in FIG. 2, the mapping platform 131 includes one or more components for determining object utility for personalizing services for space utilization according to the various embodiments described herein. It is contemplated that the functions of the components of the mapping platform 131 may be combined or performed by other components of equivalent functionality. As shown, in one embodiment, the mapping platform 131 includes a sensor data module 201, a utility module 203, a volume module 205, a cost module 207, an output module 209, and a service module 211. The functions of these components are described with respect to the figures below.

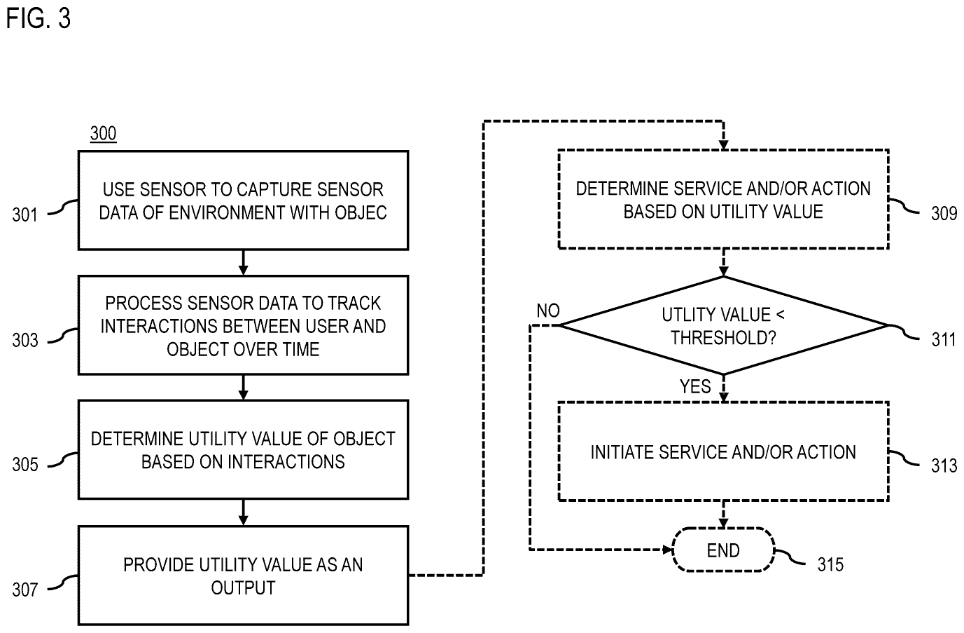

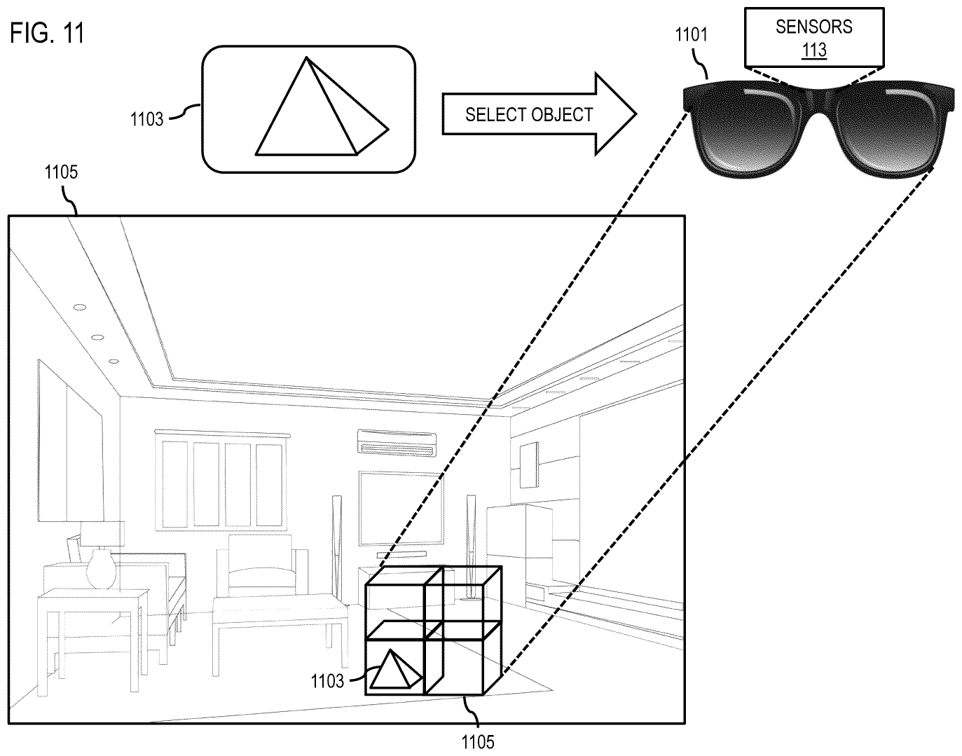

FIG. 3 is a flowchart of a process for associating an object 101 with a spatial budget 119, according to one example embodiment. In various embodiments, the mapping platform 131 and/or any of its modules/components may perform one or more portions of the process 300 and may be implemented in, for instance, circuitry or a chip set including a processor and a memory as shown in FIG. 11. As such, the mapping platform 131 and/or any of its components/modules can provide means for accomplishing various parts of the process 300, as well as means for accomplishing embodiments of other processes described herein in conjunction with other components of the system 100. Although the process 300 is illustrated and described as a sequence of steps, it is contemplated that various embodiments of the process 300 may be performed in any order or combination and need not include all of the illustrated steps.

In step 301, the sensor data module 201 uses a sensor 109 to capture sensor data 115 of an environment (e.g., the available space 103) including an object 101 over a period of time (e.g., any designated time period such as but not limited to a week, month, etc.). In step 303, the sensor data module 201 processes the sensor data 115 to track one or more interactions between at least one user (e.g., person) and the object 101 over the designated period of time. In one embodiment, the tracking can occur progressively over time such that interactions are tracked as data is collected or otherwise becomes available. In other embodiments, the processing of the sensor data 115 to track objects can be performed as a batch process at the end of each data collection time period (e.g., over a designated number of the most recent time epochs or over all time epochs during which the sensor data 115 is collected).

In one embodiment, to track object usage, the sensor data module 201 uses various sensor inputs by which the usage of an object could be tracked. These various sensor inputs include but are not limited to: (1) Camera sensors 109 plus image recognition (e.g., machine learning-based image recognition); (2) head-mounted display/smart glasses with sensors 109 (e.g., camera, LiDAR, etc.) plus image recognition; (3) tracking sensors 109 in or on objects 101; (4) infrared sensors 109 for generating an infrared image of objects 101 (e.g., to derive touch data 117 from hotspots in the infrared image where a user has touched an object 101); (5) gaze tracking sensors 109 to generate gaze tracking data 116; (6) LiDAR sensors 109 or devices plus feature recognition; etc.

For example, in embodiments using camera sensors 109 plus image recognition (e.g., machine learning-based image recognition), it is contemplated that any image recognition technique known in the art that is capable of identifying persons and objects 101 in image data 113 (e.g., video feeds) can be used according to the various embodiments described herein. For example, sensor data 115 can be captured from camera feeds covering the relevant space 103. The camera feeds (e.g., sensor data 115) are then processed using image recognition to determine a pairing of persons and objects 101. The image recognition engine, for instance, can be trained to recognize images that depict examples of a person interacting with an object 101 (e.g., a person holding/touching the object 101, a person using an object 101, a person looking at an object 101, etc.). Examples of this technology include but is not limited to “cashierless stores” that use image feeds and image recognition in place of human cashiers to determine when a user selects a store item for purchase.

In embodiments using a head-mounted display/smart glasses plus image recognition, smart glasses or equivalent wearable devices would enable the application of image recognition techniques as well but provide different points of view. For example, a user could move about while wearing the head-mounted display and capture different points of view of an environment and the objects 101 therein. In cases, where the head-mounted display is used for a longer period of time, movements and/or interactions with the objects 101 can be capture. Also, instead of covering the entire space 103 with cameras or equivalent sensors 109 to track objects 101, the area and/or duration under tracking would be greatly reduced (e.g., to the field of view of the head-mounted display/smart glasses and the time period during which the head-mounted display is worn), thereby increasing user privacy.

In one embodiment, tracking sensors 109 (trackers) can be placed in or on objects 101. For example, tracking sensors 109 can include but are not limited to trackers that use short range wireless technology (e.g., low energy Bluetooth, near field communication (NFC), etc.) for object location and tracking. In other examples, the objects can be IoT devices with positioning sensors, orientation sensors, etc. The trackers could signal that an object 101 was moved, indicating usage or interaction. It is contemplated that various types of sensors could be used for that purpose (e.g., accelerometer, proximity sensors, interaction with the interface of the device, etc.). Additionally, small sensors 109 (e.g., in the form of stickers) could be placed on top of objects 101 to track their usage/interactions and removed later on.

In embodiments using infrared sensors 109 to generate a literal heatmap, humans interacting with objects leave a trace of heat on the surface of those objects 101. With an infrared sensor 109 or equivalent, an object 101 having been handled could therefore be tracked. In one embodiment, a LiDAR scan can be used to determine the type of material an object 101 is made of to calibrate or determine the heat dissipation properties of the object 101 for tracking.

In some embodiments, gaze tracking sensors 109 and gaze tracking data 116 can be used to determine object usage or interaction. Not every object receives its utility from being touched. For example, paintings, television sets, and/or the like instead are “used” by looking at them. Identifying objects 101 that are being looked at therefore adds an additional factor when computing an object's utility value 105.

In some embodiment, LiDAR sensors 109 or devices can be used to determine usage or interactions with objects 101. For example, a machine learning (ML) model could learn from user interactions with objects 101, which could be done leveraging LiDAR sensors 109 or equivalent inside a room.

In step 305, the utility module 203 determines a utility value 105 of the object based on the one or more interactions or usage data determined above. According to one example, the definition of utility value can be defined as: “Utility is a term in economics that refers to the total satisfaction received from consuming a good or service. Economic theories based on rational choice usually assume that consumers will strive to maximize their utility.” Automatically quantifying this object utility value 105 using machine-based processes is a technical challenge solved by the various embodiments described herein.

In one embodiment, there is a difference between object usage and utility. From tracking object usage, we can arrive at usage metrics such as but not limited to:
Fraction of days during which an object 101 was used;
Average number of minutes per day that an object 101 is used; and
Longest span in number of days for which an object 101 has not been used.

However, in some embodiments, ranking objects 101 purely according to usage metrics may not result in identifying treasured objects that are not often used. This is because, in some cases, the duration of an interaction does not necessarily correspond with how valued that interaction was for the person interacting. This different in value is captured by the term “utility.”

In one embodiment, factors that can drive utility (e.g., affect the computation or determination of the object utility value 105) include but are not limited to a machine-detectable emotional state of user when interacting with or using an object 101. One example of a detectable emotional state is joy. Generally, measuring joy is technically challenging, but is a one driver for measuring object utility value 105. Playing on an instrument for example might have a much higher subjective joy value than loading the dishwasher for the same amount of time.

In one embodiment, the sensor data module 201 can collect sensor data 115 to measure joy by measurements such as but not limited to:
Detected emotions on the face of the user (e.g., via image data 113 and image recognition);
Biometric measurement (e.g., heart rate, respiratory rate, etc.) using wearable devices such as but not limited to smart watches, fitness trackers, etc.;
Speech analysis of how the person talks when using an object 101 or after interacting with it (e.g., by recognizing words associated with joy or any other selected emotional state in capture audio or speech data); and
The way the object 101 is dealt with or handled (with care or not) (e.g., via image data 113 and image recognition for user interactions).

Another example of a factor that can be used when determining object utility value 105 is a necessity of the object 111. As used herein, “necessity” is a classification that can be applied to an object 101 to designate that the object 101 is a functional object 101 with no utility value or for which a utility value would not be application. For example, a dishwasher, while not being a particularly joyful device, serves a crucial daily function and would typically have a high usage or interaction. So, focusing on joy only might yield counter-intuitive results. To address this technical issue, the utility module 203 can be configured to mark certain objects 101 (e.g., like household appliances) as a necessity that is “to be ignored” for the purposes of determining object utility values 105 based on the assumption that computing their utility is not needed because their presence is non-negotiable anyhow. However, this approach might lead to an inflation of objects 101 to be ignored and fail to capture the low utility of certain appliances or other marked item types (e.g., the low utility value of a mostly unused special kitchen device).

Accordingly, in an alternative embodiment, the utility module 203 can define an object 101 as an appliance (or equivalent necessity object) and assign a constant utility value for them, replacing the joy-based (or other emotional state based) utility measure.

It is noted that the above example of factors or drivers (e.g., joy, necessity) to consider when computing the object utility value 105 is provided by way of illustration and not as limitations. It is contemplated designated utility drivers other than detectable emotional state of the user, necessity of the object, etc. and object classes associated with the drivers can be used according to the various embodiments described herein. One example, but not exclusive, algorithm for computing the object utility value 105 is as follows:
(1) Determine object class of an object 101;
(2) Determine utility type (e.g., joy-based, any other emotional state-based, necessity-based, etc.) to apply based on object class; and
(3) Apply utility computation function (e.g., receives object usage/interaction patterns and additional inputs associated for that type of utility).

In one embodiment, the utility module 203 can use object usage or interaction to determine a correlation with the object 101's utility even without using the utility drivers described above. Whenever an object 101 is entirely unused, for example, the utility module 203 can determine that the object 101 does not possess utility without worrying about the exact utility value. On the other side of the spectrum, observing that an object 101 is used daily (or above a threshold frequency) is indicative of the object 101's utility as well.

In one embodiment, the utility module 203 can compute the object utility values 105 for objects 101 based directly on their usage and/or interaction data. Then, the additional utility drivers (e.g., joy, etc.) can be used when comparing objects 101 that have a similar amount of usage.

In one embodiment, the utility value is determined using a trained machine learning model based on one or more attributes of the object 101, the one or more interactions (e.g., object usage data), the environment (e.g., available space 103), an associated context (e.g., time, season, weather, event, etc.), or a combination thereof. Thus, in one embodiment, the various embodiments for determining object utility values 105 can be improved with machine learning. For example, the utility module 203 via an ML system can incorporate user feedback to improve utility estimation. In other words, the utility module 203 can use a machine learning loop whereby users can provide feedback to those suggestions made by ML system, and then training the utility prediction algorithm by adapting it to the users' preferences.

As part of this process, balancing object spatial cost 121 and object utility value 105 can depend on estimating utility to a target level of accuracy. In one embodiment, the utility module 203 can be learned per individual user. While it may be hard for users to express the utility of a particular object 101 in absolute terms, putting objects' utility into relation to each other is more straight-forward (e.g., “rate the utility of your plano from 1-5” can be hard for a user to answer, but “would you rather keep your plano or this bookshelf” is likely to be much easier to answer). In other words, the utility value 105 can be computed as a “Relative utility value” so that the utility value is determined based on a relative utility ranking of the object 101 in relation to one or more other objects.

In one embodiment, by suggesting replacements of (groups of) objects 101 with other (groups of) objects 101, the system 100 will collect this sort of relational feedback. This data could therefore either be collected during normal operation as the system 100 keeps on making such suggestions (e.g., system proposes to replace X with Y; if the answer is yes, the system 100 learns Y>X, and if the proposal is refused, the system 100 learns X>Y).

In addition or alternatively, there could be a dedicated training period where the system 100 asks, via a user interface, “If you had to decide, would you rather keep A or B?”. This will lead to a collection of data entries “x>y”, where x stands for particular objects 101. This information can be used for approaches such as but not limited to:
(1) To infer a complete ordering of all objects 101 in the inventory; and
(2) To generalize from the concrete objects 101 that a user has already ranked to a forward-looking prediction that is able to better estimate utility for unseen objects 101 of the same user or even for other users. While utility may be user specific under certain embodiments, this does not mean there could not be commonalities between users. For example, there are classes of objects that tend to have a higher subjective value which the algorithm (e.g., ML model) could learn.

By way of example, this problem falls under “ordinal regression” or “learning to rank,” which sits between classification and regression. Thus, given a set of pairwise inequalities, the ML model tries to infer the proper relation for new inputs.

For embodiments of approach 1 above, the utility module 203 can obtain pairs of identifiers of objects 101, and an algorithm would be used to find the absolute ordering that violates the least of the given preferences.

For embodiments of approach 2, the utility module 203 can perform a vectorization of the objects 101, so that Transfer Learning can take place. In one embodiment, possible features for vectorization can include but is not limited to:
Type of object 101 (e.g., furniture, book, musical instrument, electronic devices, etc.);
Color (e.g., user A might have a preferred color);
Shape;
Manufacturer;
Usage patterns observed;
Etc.

With such insights, the utility module 203 and/or ML model might be able to find out or learn patterns like “people generally prefer to keep instruments than some decorative elements if they need to choose between both,” thereby improving initial suggestions for unknown objects or new users.

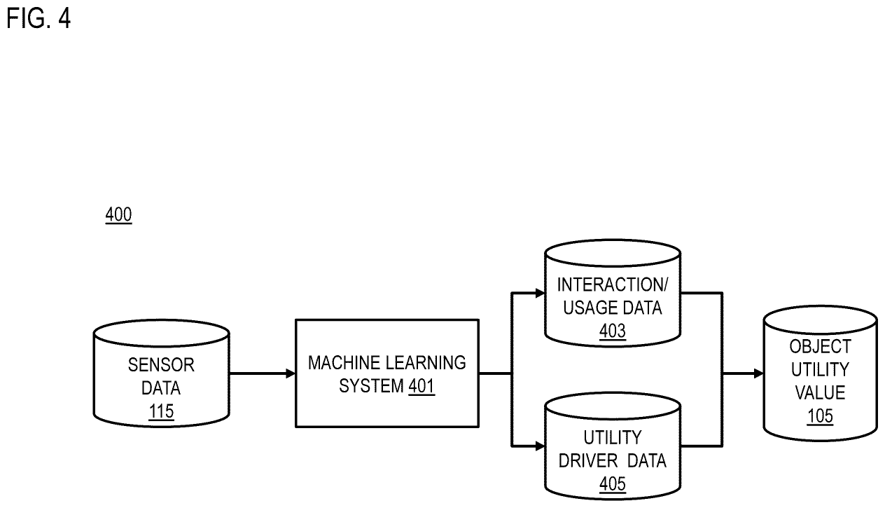

FIG. 4 is a diagram illustrating a data pipeline 400 for determining an object utility value, according to one example embodiment. The data pipeline 400 summarizes the approach of the various embodiments of step 305 of process 300. The raw sensor data 115 (e.g., depicting or otherwise representing instances of a user interacting with or using an object 101) is processed using a machine learning (ML) system 401 (e.g., trained and configured as described above) to determine object interaction/usage data 403. Object interaction/usage data 403 includes, for instance, usage patterns and/or statistics about the object interaction/usage (e.g., number of interactions/uses, frequency, time, length of usage, etc.). In one embodiment, the ML system 101 also processes the sensor data 115 to determine utility driver data 405 representing utility drivers or factors. For example, if the utility driver is the joy experienced by the user during usage or interaction with the object 101, the ML system 401 can be trained to recognize facial features or other user features that are indicative of joy or any other designated emotional state (e.g., sadness, displeasure, etc.). The joy features can then be tracked over time to determine how often, how long, intensity, etc. the user is classified as experiencing joy by the ML system 401. These statistics or data are provided as the utility driver data 405. The interaction/usage data 403 and utility driver data 405 can then be used as parameters for computing the object utility value 105. One example equation for computing the object utility value 105 is provided by way of example and not as a limitation below:

object utility value 105=w₁(interaction usage data 403)+w₂(utility driver data 405)
where w₁=a first weighting factor assigned to the interaction/usage data 403, and w₂=a second weighting factor assigned to the utility driver data 405. In one embodiment, the object utility value 105 can be normalized to a designated range (e.g., 0.0 to 1.0).

In step 307, the output module 209 provides the utility value as an output. In one embodiment, the output can be provided to one or more components of the system 100 (e.g., services platform 125, services 123, and/or content providers 143) or components with connectivity to the system 100. It is contemplated that the output can be used by the mapping platform 131 and/or any other components to provide one or more services and/or applications such as described below with respect to optional steps 309-315.

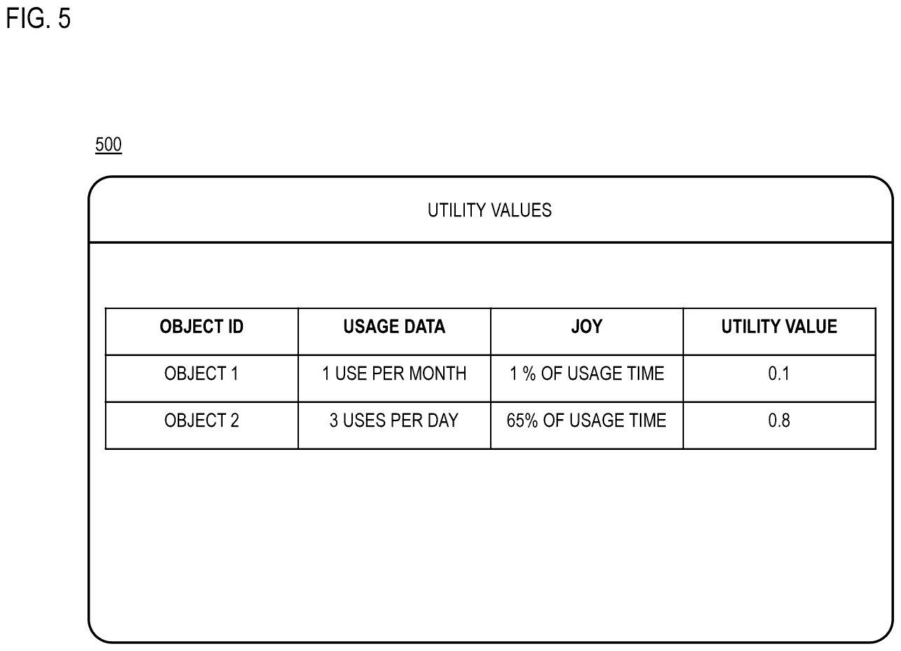

FIG. 5 is a diagram illustrating an example user interface 500 for presenting an object utility value, according to one example embodiment. In this example, Object 1 and Object 2 are tracked over a three-month period to determine usage data and joy data for determining a respective object utility value. Object 1 is determined to have a usage rate of 1 use per month and during use of Object 1, the corresponding user was detected to have a facial expression corresponding to joy for 1% of the usage time resulting in a normalized utility value of 0.1. Object 2 is determined to have a higher usage rate of 3 uses per day and during use of Object 2, the corresponding user was detected to have a facial expression corresponding to joy for 65% of the usage time resulting in a normalized utility value of 0.8.

In optional step 309, the service module 211 determines a service, an action, or a combination thereof to apply to the object based the utility value. In one embodiment, the service relates to one or more space utilization services such as storage services for physically storing objects 111 offsite from the available space 103 in which the objects 101 were originally stored or placed. The actions can be related to placement, storage, selling, renting, disposing, lending, etc. the one or more objects 101. These actions can be performed independent of or through one or more corresponding services (e.g., storing the object 101 in a selected storage service 123 where the service module 211 automatically recommends or initiates a service reservation or request with the storage service 123). In other words, once the system 100 is able to track object usage, the service module 211 (and/or any of the services 123) can determine how to make use of it (e.g., recommended actions and/or services) and present these the available service/action options to the user. In some embodiments, the system 100 can provide triggering criteria (e.g., when an the object utility value 105 for a given object 101 is or falls below a threshold value) to determine when the recommended service and/or actions can be automatically initiated (e.g., without further user intervention or on confirmation of the service and/or action from the user).

The service module 211 alone or in combination with the services platform 125 and/or services 123 can process the output (e.g., object utility values 105) to perform various actions/functions that are optionally associated with a service 123. For example, the output module 209 interacts with the service module 211 to reveal objects 101 which take much space (e.g., has a spatial budget 119 or spatial cost 121 above a threshold value with respect to the available space 103) and provide little utility value (e.g., has an object utility value 105 below a threshold value).

In one embodiment, by combining the computed values of “space taken by objects 101” (e.g., spatial cost 121) at home or other available space 103 and the object 101's utility value 105, the utility module 203 can compute a new indicator:

$$indicator = \frac{object utility value 105}{object spatial cost 121}$$

This indicator can be computed for each object 101 of interest (e.g., objects 101 contained within the available space 103) and then be used to show a ranking of objects 101 with the lowest indicator values, which are the most likely candidates to be considered for optimizing the home space because they are “expensive” in terms of used space and do not seem to be much used or interacted with. Various embodiments for computing object spatial cost 121 and object spatial budget 119 are described in more detail further below. In other words, in one embodiment, the service module 211 determines a spatial cost 121 and/or spatial budget 119 of the object within the environment. The service, the action, or the combination thereof is determined further based on the spatial cost 121 and/or spatial budget 119.

In one embodiment, the utility module 203 can also determine the “expected use patterns” per object 101. Usage patterns refer to aggregate usage statistics for a given object 101 (e.g., number of uses per week, length of usage, emotional state—e.g., joy—during use, etc.). For example, the system 100 can learn across people and homes/spaces 103 the typical usage patterns to be expected for each object 101 as not all objects 101 are designed to be used every day or at every season. Such information/patterns could also be communicated by manufacturers so that their objects 101 do not end up with very low utility scores without a good reason.

In one embodiment, the determining of the utility value comprises determining a context associated with the utility value 105. The service, the action, or a combination thereof is then determined based on the context. By way of example, the context includes but is not limited to a temporal context, a weather context, a user emotional state, or a combination thereof. For example, the seasonality of some objects 101 needs to be taken into account as some goods are designed for summer while some others are for winter. A Fondue/Raclette set, for instance, is mostly used during the winter.

By way of the example, the services and/or actions determined based on object utility value 105 alone or in combination with object spatial cost 121 and/or object spatial budget 119 can be used for many applications including but not limited to:
(1) Prioritize objects 101 that users could get rid of or move to a different location;
(2) Get a weekly/monthly report of the objects 101 which are the most/least “used”;
(3) Recommend not to buy an object 101 or good because of predicted utility/spatial usage; and
(4) Recommend what to swap a newly purchased object 101 for (or an object 101 “about to be purchased”).

In one embodiment, the system 100 can take into account privacy related considerations to determine object utility values 105. For example, based on a user's sensitivity to the collection and/or use of sensor data 117 or the object usage/interaction data derived therefore, users can configure which of the above-mentioned technologies they would prefer to leverage in order to benefit from the object tracking and object utility value related services.

Other example of services and/or actions that can be recommended based on object utility values 105 include but are not limited to:
Some people may not want/need object tracking technologies in their home every day, therefore such objects/devices/sensors could be rented just the time to get enough insights for those users, e.g., for a temporary period of time such as but not limited to 3 months.
Compute a “Rest map” where objects 101 are placed more than a designated period of time (e.g., 3 sec).

As previously described, in one embodiment, the service module 211 can suggest optimizations with respect to object placement, storage, etc. For example, the service module 211 can propose removing particular objects 101 that have high cost (e.g., high spatial cost 121) and low utilization (e.g., low object utility value 105).

In one embodiment, the recommended service and/or action relates to storage as a service. Similar to the suggested optimizations proposed above, but instead of just proposing to remove an object 101 that has high cost and low utilization, the service module 211 can propose a service 123 to put the object 101 into temporary storage. For example, physical objects 101 could be checked into and out of storage, with a degree of automation by system 100 and transparency to be determined by the user.

Example interactions to trigger storage and retrieval of objects 101 placed into a storage service 123 include but are not limited to:
Service reaches out to user after analyzing cost and utility: “System thinks this object could go into storage based on the following analytics data collected over the past 6 months”.
Service reaches out based on seasonal patterns: “This object could be moved into storage until next summer based on seasonality patterns and weather forecast”.

In one embodiment, the service module 211 can recommend a service and/or action based on actual and/or potential user purchases. For example, the service module 211 and/or associated service 123 can be configured to respond to user queries or input. In one example, a user asks the service module 211 and/or service 123: “Which objects would I have to put into storage (while minimizing lost utility) to have space for a) this new object I want to buy or b) an item in storage I want to bring back?” To respond to this query, the service module 211 determines the object utility values 105 and associated spatial costs 121/spatial budget 119 of the new, existing, and/or stored objects 101 to provide a response. The response can be computed based on replacing an existing or stored object 101 with lower utility values 105 than predicted for the new object 101.

In one embodiment, the service module 211 can provide object utility analytics over dynamic developments. Examples include but are not limited to analytics related to:
Trends—what are my objects that got more/less usage in the last year? This changes objects' utility and can make a person realize that something might not be needed any more (or by extrapolating this data will not be needed sometime soon).
Volume cost can be connected to economic cost by connecting it to rent associated with the space 103—e.g., as a user's rent goes up, some objects 101 might not be “justified” any more as their spatial cost 121 relative to its utility value 105 could exceed the threshold defined by a user for a given object 101. For example, “this armchair in the corner of the room was fine to place in the room 10 years ago when rent was $1,000 per month but now that the rent is $1,700, the user does not use it enough to justify the virtual real estate cost it has.”

In one embodiment, the service module 211 can recommend services and/or actions once objects 101 are already in storage. The services and/or actions include but are not limited to keeping track of un-retrieved objects 101 in storage, and propose to sell, rent, lend, etc. on one or more services 123 (e.g., auction or marketplace services 123). For example, a storage service 123 could be seen as a temporary external storage out of a user's home or space 103. Then, if the user does not need a given object for designated time period (e.g., not needed in 3 years), the service module 211 can present a recommendation (e.g., via a device user interface) to sell the unneeded object 101. In one embodiment, the service module 211 can interface with a service 123 to generate an automatic offer or listing to sell, give away, remove, rent, lend, and/or otherwise dispose of the object 101 that the user could validate with one click. In some embodiments, the user can configure the service module 211 to sell or otherwise dispose of the object via a service 123 automatically without further user intervention after a period of no use, or if the object 101's utility value 105 drops below a threshold value. To prepare the listing on the service 123, the service module 211 can leverage pictures, descriptions, and/or other metadata which were automatically taken at the time the object 101 was sent to storage.

In one embodiment, users can tag objects 101 as “lendable” so that instead of costing money for storage, they might bring money in form of a rental fee. In this case, the service module 211 can interface with and leverage automated systems, robots, and/or the like to make stored objects 101 available to third party people in case of such rental process. In addition, the service module 211 can connect with services 123 that facilitate connecting to the sharing economy without putting objects 101 into storage first. For example, the service module 211 can use usage patterns and/or utility values 105 as input for entries into neighborhood lending portals/services 123 to enable shared access, in particular of expensive items, e.g., if the user and a neighbor have shared access to a 4k projector or any other expensive device.

In one embodiment, the service module 211 can use the computed object utility values 105 alone or in combination with the spatial cost 121/spatial budget 119 of various objects to support interior architecture services 123. For example, based on all the collected data and analytics on object utility/usage/interactions, the system could support the design and architecture services 123 for configuring homes based on those learnings and insights (e.g., optimized placement and locations of objects 101 and associated architectural features—such as plane surfaces—with a space 103). In other words, the service module 211 can recommend the most optimal layout for scenarios such as but not limited to:
Maximizing visibility and accessibility of objects 101 having high utility and usage and conversely, placing less used objects 101 in more “hidden” places (e.g., by determining a recommended placement of the object 101 within the environment or place 103 based on the utility value 105 alone or in combination with the spatial cost 121/spatial budget 119;
Maximizing the utility value 105 of some class of objects 101 (e.g., books);
Minimizing the plane surfaces that tend to gather all the clutter/paper/mess;
Optimizing the piling up of objects 101 (e.g., furniture); and
etc.

In summary, example use cases and applications for the various embodiments described herein include but are not limited to:
Suggesting which objects 101 to store in remote places, based on utility value 105;
Suggesting to people how to make the most of the objects 101 they have in their houses and move away things which are less needed (e.g., decluttering support). In other words, the recommended action includes a decluttering of the environment or space 103, a hiding of the object 101, a displaying of the object 101, a moving of the object 101, or a combination thereof.
Selling/renting unused objects 101 which are stored in external locations, leading to additional revenue;
Possibly realizing that a user/couple does not need such a large home anymore once the home or space 103 is decluttered, leading to taking a smaller house/flat with a smaller overall footprint;
Giving people more space inside their home once the unused/unwanted objects 101 are removed;
Generate a report “Before/After” such a process is applied to show how much space has been optimized by removing low utility/high spatial cost objects 101;
Providing a recommendation engine for a move between flats/houses (e.g., what to take or not to take based on object utility value 105 alone or in combination with spatial cost 121/spatial budget 119 (e.g., generate a prioritized list of objects 101 to take or not to take based on utility values 105).

In one embodiment, the utility module 203 supports whitelisting of certain objects 101 so that users can manually register things/objects 101 that would not be eligible for being evaluated for object utility. To achieve that, user could do actions such as but not limited to:
Take a picture of an object to add it to the whitelisting;
Mention the object to a voice assistant device: “Voice assistant, do not suggest or automate any process related to this wedding picture”; and/or
Any other object identification mechanism, e.g., touch based or image recognition based.

As previously noted, the service module 211 can interact with automated and/or robotic systems to carry out recommended services and/or actions related to object utility values 105. In one embodiment, such automated systems include links to Autonomous Vehicles (AVs). In other words, all of the various embodiments described above (e.g., identifying objects to be removed from a house, picking it up, bringing it to a storage place, lending it to someone else, etc.) can be automated, with AVs playing a key role in this chain. The service module 211 can interact with one or more AV services (e.g., vehicle sharing services, taxis, etc.) to transport objects 101 for storage, lending, selling, disposal, etc. To complete the chain of automation, the service module 211 can also interface with small transport robots in external storage rooms which could help take objects 101 to rent/borrow them or to deliver or retrieve objects from AVs from their origins or to their final destinations.

In optional step 311, the utility module 203 determines whether the utility value of the object of interest is below a threshold value. At optional step 313, if the utility value is below the threshold value, the service module 311 initiates the recommended service, the action, or a combination thereof (e.g., automatically without further user intervention or on confirmation by the user). Otherwise, the process 300 ends at optional step 315.

As previously discussed, in one embodiment, the system 100 uses the object utility values 105 alone or in combination with spatial cost 121 and/or spatial budget 119 data to determine recommendation services and/or actions with respect to an object 101. The process for determining spatial costs 121 and/or spatial budgets 119 are described below.

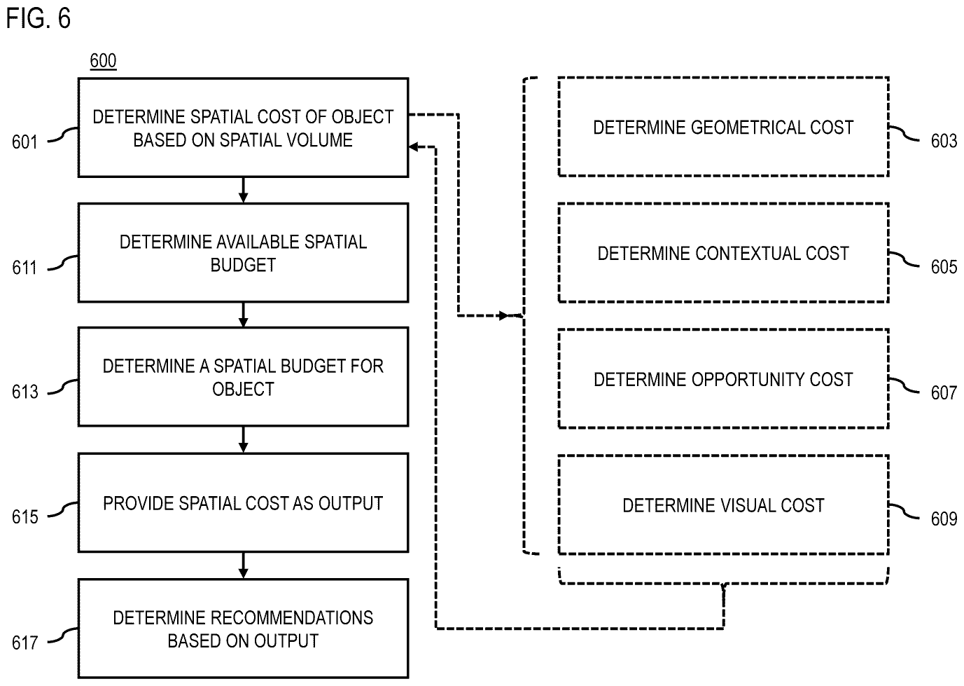

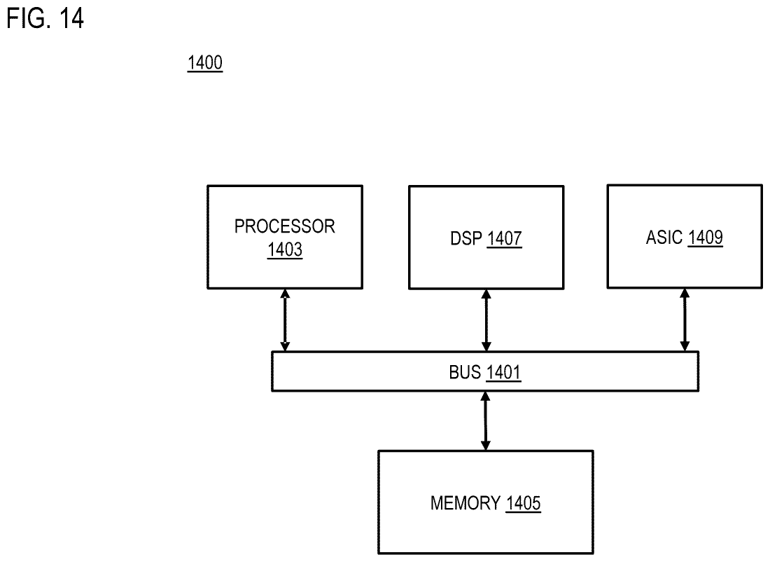

FIG. 6 is a flowchart of a process for associating an object 101 with a spatial budget 119, according to one example embodiment. In various embodiments, the mapping platform 131 and/or any of its modules/components may perform one or more portions of the process 600 and may be implemented in, for instance, circuitry or a chip set including a processor and a memory as shown in FIG. 14. As such, the mapping platform 131 and/or any of its components/modules can provide means for accomplishing various parts of the process 600, as well as means for accomplishing embodiments of other processes described herein in conjunction with other components of the system 100. Although the process 600 is illustrated and described as a sequence of steps, it is contemplated that various embodiments of the process 600 may be performed in any order or combination and need not include all of the illustrated steps.

At step 601, the cost module 207 determines a spatial cost 121 of an object 101 based, at least in part, on a spatial volume of the object 101. As used herein, the term “spatial volume” refers to the amount of space occupied by the object 101 (e.g., expressed in cubic/volumetric units such as but not limited to voxels 129). Thus, the spatial cost 121 can be represented as the number of cubic/volumetric units (e.g., voxels 129) occupied by the object 101. In one embodiment, the process for determining the spatial volume is based on whether the object 101 is a “dumb” versus “smart/connected” object 101. A “dumb” object 101 is a traditional object that does not have hardware/software to transmit information about itself (e.g., spatial volume, position within the available space 103, object identification/attributes, etc.) versus a “smart/connected” object 101 that includes such hardware/software (e.g., an Internet of Things device). For example, smart/connected objects 101 can connect to the utility module 203 (or any other component of the mapping platform 131 and/or system 100) over the communication network 133 to report their position, usage metrics (e.g., operating time, user interface interaction metrics, data throughput, and/or other object data themselves.

On the other hand, for dumb objects (or for smart/connected objects where the self-reporting function is not used), the cost module 207 interacts with the volume module 205 and sensor data module 201 to initiate a scan of the object 101 using a sensor 109 to determine its spatial volume. For example, the sensor 109 can be a LiDAR device that uses laser light to measure distances to various points in the environment (e.g., available space 103) and/or the objects 101 within the environment. A LiDAR scan is then a sweep of the LiDAR sensor device that covers a field of view of interest to generate a 3D point cloud or mesh representing the surfaces within the environment reflecting the laser light. Image segmentation and/or object recognition (e.g., using a machine learning-based feature detector) can be used to segment and extract the portion of the point cloud corresponding to an object 101 of interest. The determining of the spatial volume of the object 101 is then based on the scan (e.g., computing the spatial volume from the LiDAR point cloud data of the object 101). It is noted that the example of using a LiDAR scan described above is provided by way of illustration and not as a limitation. It is contemplated that an equivalent process can be used for other sensor types including but not limited to camera sensors (e.g., where images of the environment and/or object can be processed to determine the spatial volume of the object 101 of interest). In some embodiments, the spatial volume of the object 101, dimensions from the spatial volume can be computed, and/or other attributes of the object 101 can be manually specified, e.g., via a user interface (UI) if a device (e.g., UI of an application 135 executing on the UE 111).

In one embodiment, the cost module 207 can consider additional cost factors in addition or as an alternate to the spatial volume of the object 101 when computing the object spatial cost 121. These optional cost factors include but are limited to:
Geometrical cost;
Contextual cost;
Opportunity cost; and
Visual cost.

The various embodiments for determining these optional additional cost factors are respectively described in optional steps 603-611 below.

At optional step 603, the cost module 207 determines a geometrical cost 139 of the object 101 based on a shape of the object 101. In one embodiment, the geometrical cost 139 is any additional volume that is blocked because of the shape of the object 101. For example, as described further above, a pyramid has a lower volume than a cube of the same base and height, but the pyramid takes up as much effective volume as the cube, because the “unused” volume (e.g., the difference between the spatial volumes of the pyramid and cube) cannot be used to store or place any other object 101. The difference in spatial volume between the pyramid and the cube can be computed as a geometrical cost 139 of an object 101 with a pyramidal shape.

More generally, in one embodiment, the cost module 207 can determine a geometrical cost 139 of the object 101 based on a number of one or more standard geometrical volumes/shapes (e.g., a voxel 129) occupied by the shape of the object 101. With respect to the pyramid and cube example above, the pyramid would occupy a single voxel 129 with length, width, and height equal to the base and height as the pyramid but not fill the space of the voxel fully. The difference or unused space in the voxel 129 is the geometrical cost 139 of the pyramid. In contrast, the cube would fully occupy a voxel 129 with the same length, width, and height equal to the cube. Thus, the difference or geometrical cost of a cube would effectively be zero.

In one embodiment, there might be a difference in the perception of how full a room or available space 103 is between objects 101 of different shapes (e.g., differences in perception of the pyramid and the cube). In this case, the computed difference between a given shape of an object 101 and the standard geometrical volume or shape (e.g., the geometrical cost 139) can be weighted based on the differences in perception. For example, the weight can be determined based on user preference information collected from individuals or groups of individuals, determined based on the amount of unused space associated with a shape (e.g., shapes with more unused space are weighted less with respect to making a room appear more full), and/or the like. Thus, the unused or additional volume associated with different shapes can treated differently in different contexts with respect to computing a geometrical cost 139 associated with the shape of the object 101.

At optional step 605, the cost module 207 determines a contextual cost (e.g., part of other cost data 141) of the object 101 based on one or more additional volumes of the available space 103 that would be rendered unavailable to another object by the storage or the placement of the object 101. The spatial cost 121 of the object is further based on the contextual cost. In other words, the contextual cost is any additional volume that the object 101 would render unusable in a specific surrounding, e.g., relative to a concrete location in the available space 103 (e.g., a home, apartment, place, etc.). In one embodiment, the term “unusable” refers to any additional volume (e.g., in proximity to the placement/storage location of object 101) where the object 101 would prevent any other object 101 from being placed or stored. For example, it may be impractical or difficult to put another object 101 on top of a pyramid or similar shapes which may require precarious balancing of other objects 101 on top or where the stacked objects 101 may be unstable. In that case, the additionally lost volume in a room or available space 103 is the distance between the tip of the pyramid and the ceiling. In yet other cases, stacking or placing objects on top, below, adjacent, etc. may be incompatible based on the nature of the objects (e.g., stacking objects on a lamp may block light from the lamp or be subject to lamp's heat, placing objects in a way that can block vents or other input/output areas of other objects, etc.). Thus, the contextual cost can be based on the types of objects 101 and their limitations with respect to blocking placement of other objects adjacent or near the object 101.

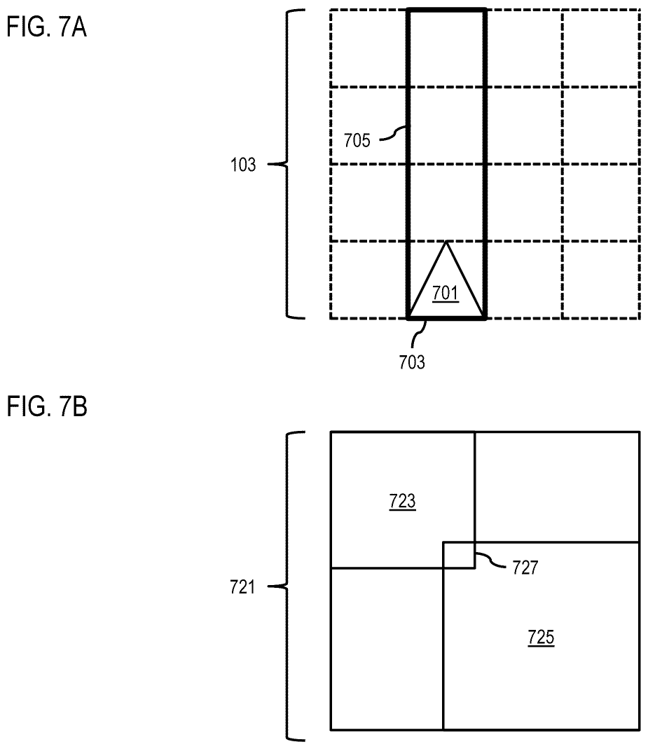

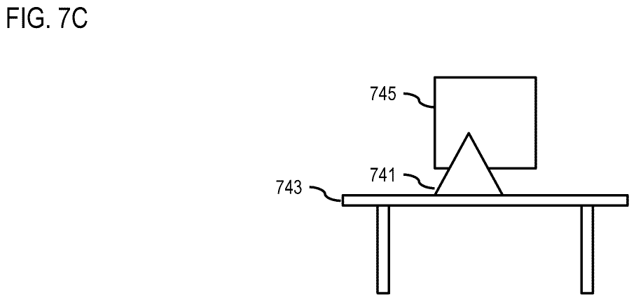

FIG. 7A is a diagram illustrating an example of contextual cost, according to one example embodiment. In this example, an available space 103 is shown from a side view with the top of the diagram representing the ceiling and the bottom the floor. Each block or grid cell in the diagram represents a cross section of a voxel dividing the available space 103. A pyramidal object 701 is placed at location 703 on the floor, and a contextual cost is computed for the pyramidal object 701 based on whether other objects can be stacked on top. In this case, because of the object 701's pyramidal shape, no other object can be stacked on top because they would simply fall off. Accordingly the contextual cost 705 would extend beyond the voxel containing the object 701 at location 703 up the ceiling to encompass three additional voxels (e.g., indicated by a bolded boundary around the total spatial cost of the object 701).

In one embodiment, additional other cost data 141 can be computed if several objects 101 are considered together.

For example, at optional step 607, the cost module 207 determines an opportunity cost of the object based on an area of a plane surface that would be rendered unavailable to another object by the storage or the placement of the object. The spatial cost 121 of the object is further based on the opportunity cost. FIG. 7B is a diagram illustrating an example of an opportunity cost, according to one example embodiment. In the example of FIG. 7B, consider a plane surface 721 of 100×100 cm, a first object 723 measuring 30×30 cm and a second object 725 measuring 80×80 cm. By putting the 30×30 object 723 on the plane surface 721 (e.g., a table surface), the area becomes unavailable for the 80×80 object 725. Accordingly, placing the first object 723 on the plane surface 721 may require relocating the second object 725 to another plane surface of at least 80×80 area because there would not be enough space for both objects 723 and 725 to be placed on the plane surface 721 at the same time (e.g., indicated by overlap 727). If there is no other area or plane surface available for either of the objects, this results in an opportunity cost of the 30×30 cm that goes beyond any of the costs associated only with the objects itself as listed above.

At optional step 609, the cost module 207 determines a visual cost of the object based on determining that the storage or the placement of the object blocks a line-of-sight view to another object. The spatial cost 121 of the object is further based on the visual cost. For example, as shown in the example of FIG. 7C, the placement or storage of an object 741 at certain locations in the available space 103 (e.g., on a table 743) might be blocking the view on another objects 745 (e.g., a frame with family pictures, a window, etc.). In one embodiment, the cost module 207 can perform line of sight computations within the corresponding available space 103 to reveal such “visual costs.” The line-of-sight computations can be computed from one or more selected locations within the available space 103 (e.g., from known seating locations, designated viewing locations, a central location, etc.). The visual cost can also be based on the percentage of the other object (e.g., object 745) visually blocked by the placed object or object of interest (e.g., object 741). In one embodiment, the visual cost can be applied as a weighting factor to the associated voxel or volumetric unit associated with the blocked line of sight.

In one embodiment, after determining one of more of the cost factors discussed with respect to the various embodiments described above, the cost module 207 computes the spatial cost 121 of an object from an aggregation of one or more selected cost factors (e.g., spatial volume, geometrical cost, contextual cost, opportunity cost, visual cost, and/or the like). The object spatial cost 121, for instance, can include aggregation all of the volumes (e.g., voxels 129 and/or any other equivalent volumetric unit) associated with the cost factors determined for the object 101.

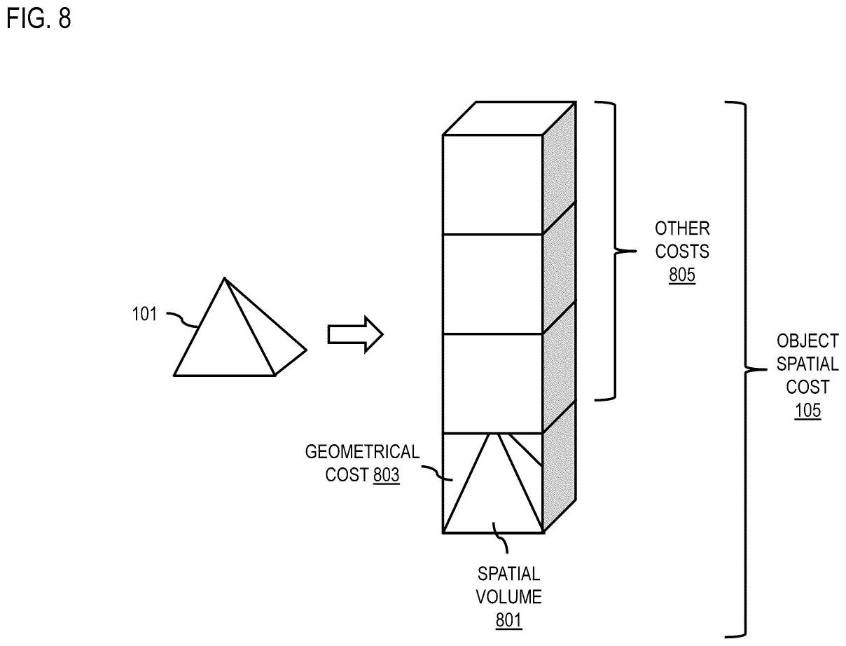

FIG. 8 is a diagram illustrating an example representation of an object spatial cost 121, according to one example embodiment. In the example of FIG. 8, an object 101 is selected for computation of a corresponding object spatial cost 121. To perform the computation, the cost module 207 determines the spatial or net volume 801 of the object 101. The cost module 207 also determines the geometrical cost 803 and/or other selected costs 805 (e.g., contextual cost, opportunity cost, and/or visual cost) according to the various embodiments described herein. The object spatial cost 121 is then represented as the aggregation of the spatial volume 801, geometrical cost 803, and other costs 805.

In one embodiment, the cost module 207 can further represent the object spatial cost 121 as an object spatial budget 119. For example, at step 611, the cost module 207 determines the available spatial budget 127 for the available space 103 in which an object 101 is placed/stored or requested to be placed/stored. To determine the available spatial budget 127, the volume module 205 partitions the available space into one or more voxels 129 (or other equivalent volumetric unit). In this way, the available spatial budget 127, the spatial budget 119 of the object 101, the spatial cost of the object 101, or a combination thereof can be represented based on the one or more voxels 129 or equivalent volumetric units. In one embodiment, the available spatial budget 127 is also referred to as the raw spatial budget. The available spatial budget 127 or raw spatial budget is equivalent to the volume of the available space 103 for placing one or more objects (e.g., space associated with a house, and/or any other place). By way of example, the raw spatial budget can be calculated according to the following or equivalent:

available spatial budget 107=area×height−slopes
where area is the area of the available space 103, height is the height of the available space 103, and slopes is the volume in the available space 103 corresponding to sloped walls or surfaces.

At step 613, in one embodiment, the volume module 205 also computes the used spatial budget (e.g., object spatial budget 119) representing the volume in the available space 103 taken by objects 101, e.g., considering their net spatial value and/or other spatial cost factors (e.g., geometrical costs, contextual costs, etc.).

One example equation for computing the object spatial budget 119 (e.g., used spatial budget) includes but is not limited to:

$$Object Spatial Budget 119 = ( \frac{Object Spatial Cost 121}{Available Spatial Budget 127} )$$

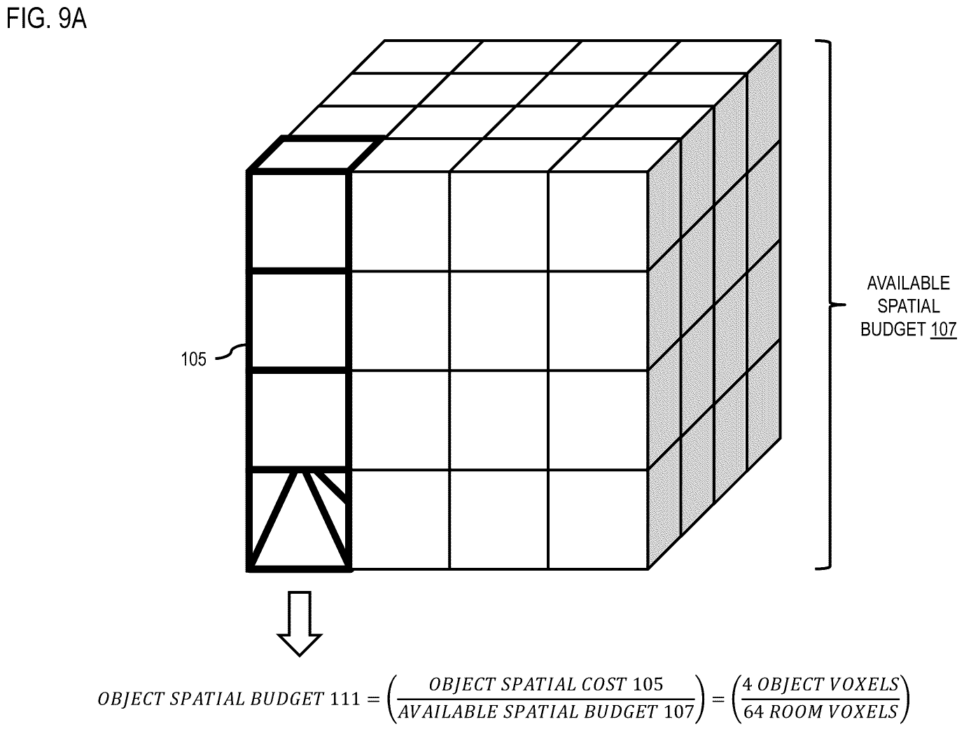

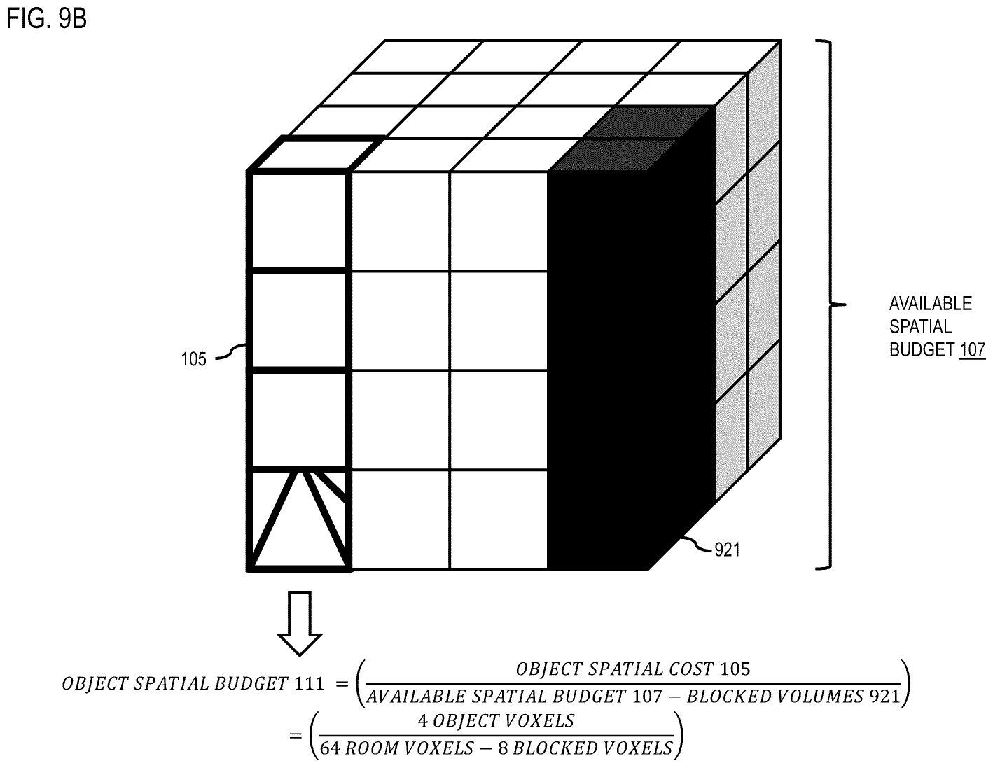

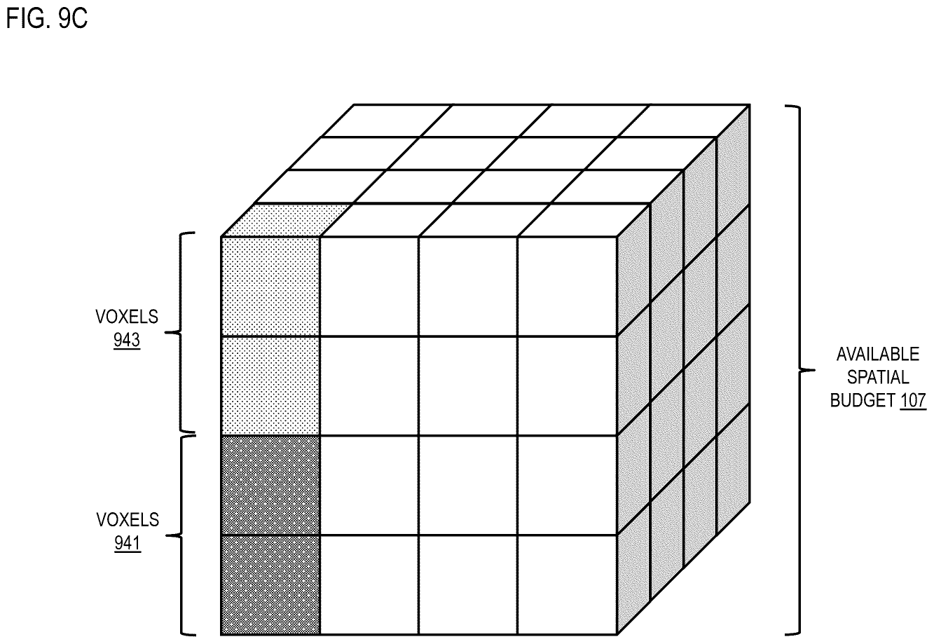

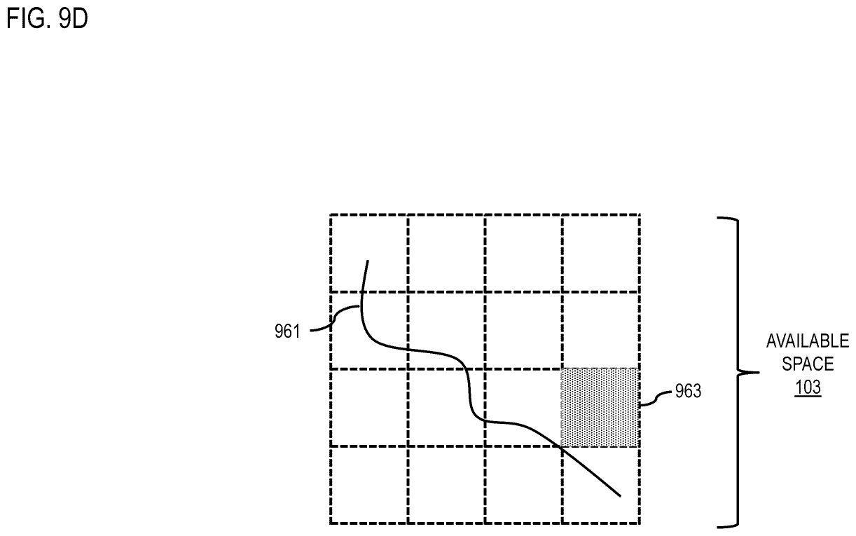

FIG. 9A illustrates an example of computing an object spatial budget 119, according to one example embodiment. In this example, the object spatial cost 121 is computed as 4 object voxels and the available spatial budget 127 is computed as 64 room voxels. The object spatial budget 119 is then computed as follows:

$$Object Spatial Budget 119 = ( \frac{Object Spatial Cost 121}{Available Spatial Budget 127} ) = ( \frac{4 Voxels}{64 Voxels} )$$

In one embodiment, the volume module 205 is configured to account for blocked volumes (e.g., blocked voxels) in the available space 103. In other words, some parts of the available space 103 may not be available for object placement or storage, e.g., areas in front of doors or windows. These volumes can be subtracted from the available spatial budget 127 (e.g., raw spatial budget) similar to the used spatial budget in order to arrive at the truly available budget.

$$Object Spatial Budget 119 = ( \frac{Object Spatial Cost 121}{Available Spatial Budget 127 - Blocked Volumes 921} )$$

FIG. 9B illustrates an example of computing an object spatial budget 119 with blocked volumes 921, according to one example embodiment. In this example, the object spatial cost 121 is computed as 4 object voxels, the available spatial budget 127 is computed as 64 room voxels, and the blocked volumes 921 is computed as 8 voxels (e.g., volume in front of a door that is unavailable for object placement/storage to avoid blocking the door). The object spatial budget 119 is then computed as follows:

$$Object Spatial Budget 119 = ( \frac{Object Spatial Cost 121}{Available Spatial Budget 127 - Blocked Volumes 921} ) = ( \frac{4 Voxels}{64 Voxels - 8 Blocked Voxels} )$$

In one embodiment, besides fully blocking particular units of space as forbidden (e.g., as described above, different voxels 129 or volumetric units might have a different value with respect to their effect on the object spatial cost 121 and/or object spatial budget 119, and this assignment of voxel to value might even differ per person, per object 101, available space 103, place, environment, and/or other equivalent contextual factor. To address this potential, in one embodiment, the cost module 207 can apply a different unit to measure the cost of an object 101, where instead of the volume consumed, the cost is the aggregated utility of all voxels consumed (utility cost or metric). Accordingly, the cost module 207 can compute a utility metric or cost respectively for the one or more voxels (or other volumetric units) based on a utility function. The spatial cost of the object is further based on the utility metric.

In one embodiment, the utility of a voxel or volumetric unit can also be dependent on other voxels. For example, a voxel that is in the middle of an available space 103 (e.g., in the middle of the air) may have low utility because there is no easy way to place an object in the voxel unless a support mechanism (e.g., a table, shelf, etc.) is placed in nearby voxels to provide support. For example, the voxel to have a higher level of utility, it may need to voxels below it to be occupied (e.g., to allow stacking or placement of objects 101). Thus, the utility of voxels within the available space 103 can be dynamically recomputed as voxels with available space 103 are occupied.

FIG. 9C is a diagram illustrating an example of assigning different utility metrics or costs to different voxels or volumetric units, according to one example embodiment. In this example, the available spatial budget 127 is partitioned into 64 voxels. Voxels 941 are assigned a high utility value and are indicated with dark shading, voxels 943 are assigned a medium utility value and are indicated with medium shading, and the remaining voxels have low utility value and are not shaded. Objects 101 that occupy voxels 941 would inherit higher spatial costs (e.g., have higher weights apply to boost spatial costs) relative to objects 101 that occupy voxels 943 which would inherit medium weighted spatial costs. Similarly, the objects 101 that occupy to other voxels with low utility will have the least amount of utility weighting. For example, voxels 941 may correspond to an area of the available space that is the user's favorite or most frequently used location, that corresponds to a position with the best view outside of the space, etc.

In one embodiment, the utility metric or utility function can be based on user specified preferences, usage history of the space, room features (e.g., windows, lights, amenities, etc.) present in the available space 103, and/or the like). For example, the utility metric or cost can be based on a user's mobility graph indicating the most frequently used or traveled locations within the available space 103. For example, to generate the mobility graph, the cost module 207 interacts with the sensor data module 201 to retrieve probe data collected from one or more devices moving within the available space 103. For example, the sensor data module 201 can map between locations in the available space 103 and people using probe data collected by UEs 111 traveling in the area. In one instance, the system 100 can also track users in the available space 103 using beacons, Wi-Fi, geotagging of pictures, etc. In one instance, the probe data may be reported as probe points, which are individual data records collected at a point in time that records telemetry data for that point in time. A probe point can include attributes such as: (1) probe ID, (2) longitude, (3) latitude, (4) heading, (5) speed, and (6) time. In the context of an indoor space, the system 100 can use, e.g., radio scanning with media access control (MAC) address of wireless access points (e.g., WiFi, etc.) and/or beacons (e.g., Bluetooth, near field communications, etc.) and corresponding signal strengths, which in turn, can be resolved into latitude, longitude instead of relying satellite-based positioning which may not be available indoors. The sensor data module 201 then processes the probe data to determine a mobility graph of the one or more devices. The mobility graph, for instance, indicates the locations, paths, etc. of the user within the available space 103. FIG. 9D is a diagram illustrating an example mobility graph tracing the path 961 that is most traveled within the available space 103 (e.g., partitioned into voxels). The diagram of FIG. 9D also indicates the voxel 963 in which there are the most number of stops by users. In one embodiment, the utility metric is determined based on the mobility graph. For example, voxels through the path 961 passes can be assigned higher utility metrics/costs. Voxel 963 with the most number of stops (e.g., rest areas) can also be assigned a higher utility value. In other words, the cost module 207 can use the mobility graph (e.g., historical mobility patterns) to learn the most walked paths and most used rest areas in order to give them special values/attributes.

In one embodiment, the cost module 207 can also value the presence of plane surfaces (e.g., horizontal and/or vertical surfaces) more highly than other features because they constitute a valued part of the “real estate” in typical environments. For example, consumers generally store or place objects almost exclusively on plane or flat surfaces. Accordingly, the sensor data module 201 can detect and record the presence of plane surfaces within the available space 103. In one embodiment, the sensor data module 101 can use sensors 109 to scan the available space 103 for plane or flat surfaces. One example of a sensor 109 includes but is not limited to a LiDAR sensor, camera sensor, and/or the like. LiDAR, for instance, can be used to scan the entire available space 103 to generate point cloud data. The point cloud data is then processed (e.g., using machine learning-based image recognition and segmentation) to identify plane surfaces.

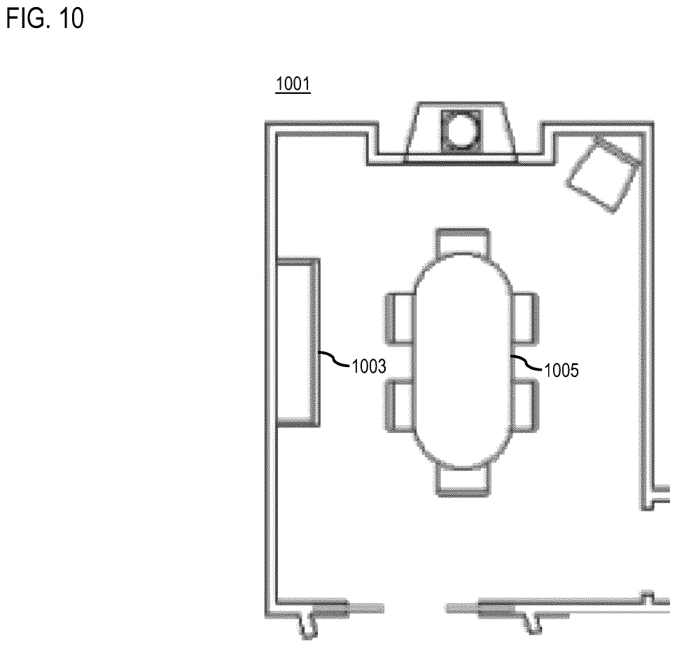

FIG. 10 is a diagram illustrating example plane surfaces for object placement, according to one example embodiment. In the example of FIG. 10, a room 1001 is scanned using a sensor 109 (e.g., LiDAR sensor). The resulting sensor data 107 is processed to identify plane surfaces in the room 1001. As shown, a plane surface 1003 (e.g., corresponding to the top surface of a side table) and a plane surface 1005 (e.g., corresponding to the top surface of a conference table 1005) are identified and mapped. In one embodiment, the volumes (e.g., voxels 129 and/or other volumetric units) corresponding to plane surfaces 1003 and 1005 can be assigned a higher utility metric.

In one embodiment, the cost module 207 determines a financial cost for the object 101 of interest based on the object spatial budget 119 and a real estate cost for the available space. For example, once an object's spatial cost 121 and the available spatial budget 127 are computed, the cost module 207 can express the spatial cost relative to the budget (e.g., the object spatial budget 119), e.g., expressed as “this object will consume 12% of your remaining spatial budget.” This object spatial budget 119 can be linked to an actual financial cost. In one embodiment, the financial cost can be computed as follows:

Financial Cost=Object Spatial Budget 111×Real Estate Cost
wherein the real estate cost is for the available space 103 in which the corresponding object 101 is placed. In other words, the financial cost is determined based on the relative cost of the object (overall spatial cost)/(raw spatial budget) and multiply this with the associated real estate cost (e.g., purchase price, monthly rent, assessed value, etc.).

In one embodiment, if the cost module 207 uses different utility metrics or costs per voxel, the relative cost can be computed as (utility cost of object 101)/(sum of utility of all voxels).

At step 615, the output module 209 provides the spatial budget 119 of the object 101, the spatial cost 121 of the object 101, the available spatial budget 127, or a combination thereof as an output. In one embodiment, the output can be provided to one or more components of the system 100 (e.g., services platform 125, services 123, and/or content providers 143) or components with connectivity to the system 100. It is contemplated that the output can be used by the mapping platform 131 and/or any other components to provide one or more services and/or applications.

For example, at step 617, the output module 209 determines recommendations for the object 101 based on the output. In one embodiment, the output module 209 can determine a recommended position to place or store the object in the available space based on the spatial budget of the object. More specifically, the output module 209 can determine whether the spatial budget 119 and/or spatial cost 121 of an object 101 permits it to be placed within the available space 103. In addition, the output module 209 can search the available space 103 for unused portions of the available space 103 in which the object 101 can be placed given its spatial budget 119 and/or cost 121. The output module 209 can take into account user preferences, spatial cost factors discussed with respect to the various embodiments described herein, properties of the object 101, properties of the available space 103, and/or the like to recommend a location for placing or storing the object.

In one embodiment, the output module 209 can also link purchases to the available spatial budget 127 or otherwise compute an object spatial budget 119 and/or cost 121 for purchases or perspective purchases. In other words, the mapping platform 131 can initiate the determining of the spatial cost 121 and/or spatial budget 119 of an object 101 based on an acquisition/purchase or a request to acquire/purchase the object 101.

By way of example, the output module 209 can provide different ways of linking the objects 101 to a spatial budget such as but not limited to:
(1) In one scenario, the user starts with no prior data and makes a full LiDAR scan (or any other type of scan using sensor 109) on her/his indoor environment in order to create a list of all items/objects 101 and their associated spatial costs 121 and/or spatial budgets 119 along with their associated locations.
(2) In another scenario, the user has an empty space and links every purchase of objects 101 made in a shop to the location where this item will be stored or placed in the available space 103, either:
   Manually, by placing an object at its location in the available space 103; or
   Automatically, by simply wearing a Head Mounted Devices (HMD) like smart glasses, which would automatically be informed about a new purchase made by this user (e.g., link to bank/credit card application programming interface (API)) and would attempt to determine its new location inside the user's available space 103 (e.g., home) once the user unpacks the objects 101.

In one embodiment, as shown in the example of FIG. 11, the output module 209 presents the output of the system 100 in a user interface (UI) of an augmented reality (AR) device or glasses 1101 (e.g., smart glasses). In this example, the glasses 1101 include sensors 109 such as a front facing camera and LiDAR. Accordingly, the various embodiments of processes described herein can be automated by leveraging regular automatic scanning of the environment, change detection, and object recognitions. For example, the glasses 1101 can scan for a newly acquired object 1103 and then automatically select the object 1103 to compute a corresponding spatial cost 121 and/or spatial budget 119 for a room 1105 visible through the glasses 1101. A representation of the object 1103 and the spatial cost 1105 of the object 1103 can be presented in the AR UI of the glasses 1101.

In summary, in one embodiment, the mapping platform 131 uses inputs such as but not limited to:
2D and 3D Map of the available space 103 (e.g., of a house, flat, and/or any other place) (e.g., queried from the geographic database 137);
Sensor data 107 of the available space 103 (e.g., a LiDAR or camera scan of the house or place of interest);
List of all objects 101/goods in the available space 103;
List of areas that are not available for placing/storing objects in the available space 103, e.g., paths to circulate, walk in the house, doorways, etc.;
Optionally, a list of high-value and low-value areas (e.g., utility metrics/costs) to assign non-equally distributed utility;
Probe data indicating human movement in the available space 103 of the place/environment of interest.

Based on one or more of the above inputs, the mapping uses the various embodiments described herein to provide outputs such as but not limited to:
Total volume and available spatial budget 127 for a given space (e.g., a house, flat, etc.);
Volume and associated costs of an object (e.g., object spatial costs 121); and
Impact of an object on a spatial budget (e.g., object spatial budget 119).

In one embodiment, as previously described, the mapping platform 131 can provide Contextual suggestions and recommendations at purchase or acquisition time for one or more objects 101. For example, when considering a purchase or acquisition, the mapping platform 131 complements the financial cost of the object 101 with the impact on a user's spatial budget (e.g., object spatial cost 121 and/or object spatial budget 119).

In one scenario, at purchase time, the mapping platform 131 determines and presents to the user (e.g., via a user interface of UE 111) a suggested area or plane surface in the available space 103 where such an object 101 would fit. If there is no such a space available in the user's space (or even if there is), the mapping platform 131 can suggest another object 101 that could be swapped against this “about-to-be-purchased item” that would have less object spatial cost 121 and/or object spatial budget 119 in the user's available space 103.

With such information, the user could make a decision such as but not limited to:
Not to buy the object, the user was considering;
Buy the suggested object 101 in addition to the previously evaluated item; and/or
Swap the prospective object 101 of interest against an older already owned item (which could be automatically uploaded to an auction website, online marketplace, and/or the like)

In various embodiments, the mapping platform 131 can use any type of user interface for surfacing the information computed according to the various embodiments described herein. For example, as previously discussed and described with respect to FIG. 11, one user interface can leverage AR and show an overlay on top of every object 101 in the available space 103 (e.g., house, flat, etc.) with its associated spatial cost 121 and/or spatial budget 119.

Another interface would present the available space 103 (e.g., room) in a smartphone/screen interface (e.g., of an application 135 executing on the UE 111), showing every object 101 on this map with the associated spatial costs 121 and/or spatial budgets 119.

In addition or alternatively, the output module 209 of the mapping platform 131 can present the objects 101 in an available space 103 in a ranked list, to quickly visualize which objects 101 have the highest associated spatial costs 121 and/or spatial budgets 119.

Returning to FIG. 1, as shown, the system 100 includes the mapping platform 131 for associating an object 101 with a spatial budget. In one embodiment, the mapping platform 131 has connectivity over the communication network 133 to services platform 125 that provides one or more services 123 that can use the object spatial cost 121, object spatial budget 119, available spatial budget 127, and related information for downstream functions. By way of example, the services 123 may be third party services and include but is not limited to object tracking services, online shopping/marketplace services, mapping services, navigation services, travel planning services, notification services, social networking services, content (e.g., audio, video, images, etc.) provisioning services, application services, storage services, contextual information determination services, location-based services, information-based services (e.g., weather, news, etc.), etc. In one embodiment, the services 123 uses the output of the mapping platform 131 to provide services such as navigation, mapping, other location-based services, etc. to the UEs 111, applications 135, and/or other client devices/applications.

In one embodiment, the mapping platform 131 may be a platform with multiple interconnected components. The mapping platform 131 may include multiple servers, intelligent networking devices, computing devices, components, circuitry, and corresponding software for associating an object 101 with a spatial budget according to the various embodiments described herein. In addition, it is noted that the mapping platform 131 may be a separate entity of the system 100, a part of one or more services 123, a part of the services platform 125, or included within components of the UEs 111.

In one embodiment, content providers 143 may provide content or data (e.g., including sensor data 107 such as LiDAR data, image data, probe data, related geographic data, object specification data such as object spatial volume data, etc.) to the geographic database 137, the mapping platform 131, the services platform 125, the services 123, the UEs 111, and/or the applications 135 executing on the UEs 111. The content provided may be any type of content, such as sensor data, imagery, probe data, machine learning models, permutations matrices, map embeddings, map content, textual content, audio content, video content, image content, etc. In one embodiment, the content providers 143 may provide content that may aid in associating an object 101 with a spatial budget according to the various embodiments described herein. In one embodiment, the content providers 143 may also store content associated with the geographic database 137, mapping platform 131, services platform 125, services 123, and/or any other component of the system 100. In another embodiment, the content providers 143 may manage access to a central repository of data, and offer a consistent, standard interface to data, such as a repository of the geographic database 137.

In one embodiment, the UE 111 may execute software applications 135 to use output of the mapping platform 131 or other data derived therefrom according to the embodiments described herein. By way of example, the applications 135 may also be any type of application that is executable on the UEs 111, such as object cataloging/tracking applications, routing applications, mapping applications, location-based service applications, navigation applications, device control applications, content provisioning services, camera/imaging application, media player applications, social networking applications, calendar applications, and the like. In one embodiment, the applications 135 may act as a client for the mapping platform 131 and perform one or more functions for associating an object 101 with a spatial budget alone or in combination with the mapping platform 131.

By way of example, the UEs 111 are or can include any type of embedded system, mobile terminal, fixed terminal, or portable terminal including a built-in navigation system, a personal navigation device, mobile handset, station, unit, device, multimedia computer, multimedia tablet, Internet node, communicator, desktop computer, laptop computer, notebook computer, netbook computer, tablet computer, personal communication system (PCS) device, personal digital assistants (PDAs), audio/video player, digital camera/camcorder, positioning device, fitness device, television receiver, radio broadcast receiver, electronic book device, game device, or any combination thereof, including the accessories and peripherals of these devices, or any combination thereof. In one embodiment, the UEs 111 can be robotic vacuums, floor cleaners, or other equivalent robotic devices capable of navigating by performing Simultaneous Mapping and Localization (SLAM) functions which could provide the base map of the available space 103 (e.g., room, home, flat, etc.). It is also contemplated that the UEs 111 can support any type of interface to the user (such as “wearable” circuitry, etc.). In one embodiment, the UEs 111 may be associated with or be a component of any other device.

In one embodiment, the UEs 111 are configured with various sensors 109 for generating or collecting sensor data 107 (e.g., LiDAR data, image data, probe data), related geographic data, etc. In one embodiment, the sensed data represents sensor data associated with a geographic location or coordinates at which the sensor data was collected. By way of example, the sensors 109 may include a global positioning sensor for gathering location data (e.g., GPS), IMUs, a network detection sensor for detecting wireless signals or receivers for different short-range communications (e.g., Bluetooth, Wi-Fi, Li-Fi, near field communication (NFC) etc.), temporal information sensors, LiDAR sensor/device, a camera/imaging sensor for gathering image data, an audio recorder for gathering audio data, and the like.

Other examples of sensors of the UEs 111 may include light sensors, orientation sensors augmented with height sensors and acceleration sensor, tilt sensors to detect the degree of incline or decline (e.g., slope) along a path of travel, moisture sensors, pressure sensors, etc. In one embodiment, the UEs 111 may include GPS or other satellite-based receivers to obtain geographic coordinates from positioning satellites for determining current location and time. Further, the location can be determined by visual odometry, triangulation systems such as A-GPS, Cell of Origin, or other location extrapolation technologies.

In one embodiment, the communication network 133 of system 100 includes one or more networks such as a data network, a wireless network, a telephony network, or any combination thereof. It is contemplated that the data network may be any local area network (LAN), metropolitan area network (MAN), wide area network (WAN), a public data network (e.g., the Internet), short range wireless network, or any other suitable packet-switched network, such as a commercially owned, proprietary packet-switched network, e.g., a proprietary cable or fiber-optic network, and the like, or any combination thereof. In addition, the wireless network may be, for example, a cellular network and may employ various technologies including enhanced data rates for global evolution (EDGE), general packet radio service (GPRS), global system for mobile communications (GSM), Internet protocol multimedia subsystem (IMS), universal mobile telecommunications system (UMTS), etc., as well as any other suitable wireless medium, e.g., worldwide interoperability for microwave access (WiMAX), Long Term Evolution (LTE) networks, 5G New Radio networks, code division multiple access (CDMA), wideband code division multiple access (WCDMA), wireless fidelity (Wi-Fi), wireless LAN (WLAN), Bluetooth®, Internet Protocol (IP) data casting, satellite, mobile ad-hoc network (MANET), and the like, or any combination thereof.

By way of example, the mapping platform 131, services platform 125, services 123, UEs 111, and/or content providers 143 communicate with each other and other components of the system 100 using well known, new or still developing protocols. In this context, a protocol includes a set of rules defining how the network nodes within the communication network 133 interact with each other based on information sent over the communication links. The protocols are effective at different layers of operation within each node, from generating and receiving physical signals of various types, to selecting a link for transferring those signals, to the format of information indicated by those signals, to identifying which software application executing on a computer system sends or receives the information. The conceptually different layers of protocols for exchanging information over a network are described in the Open Systems Interconnection (OSI) Reference Model.

Communications between the network nodes are typically effected by exchanging discrete packets of data. Each packet typically comprises (1) header information associated with a particular protocol, and (2) payload information that follows the header information and contains information that may be processed independently of that particular protocol. In some protocols, the packet includes (3) trailer information following the payload and indicating the end of the payload information. The header includes information such as the source of the packet, its destination, the length of the payload, and other properties used by the protocol. Often, the data in the payload for the particular protocol includes a header and payload for a different protocol associated with a different, higher layer of the OSI Reference Model. The header for a particular protocol typically indicates a type for the next protocol contained in its payload. The higher layer protocol is said to be encapsulated in the lower layer protocol. The headers included in a packet traversing multiple heterogeneous networks, such as the Internet, typically include a physical (layer 1) header, a data-link (layer 2) header, an internetwork (layer 3) header and a transport (layer 4) header, and various application (layer 5, layer 6 and layer 7) headers as defined by the OSI Reference Model.

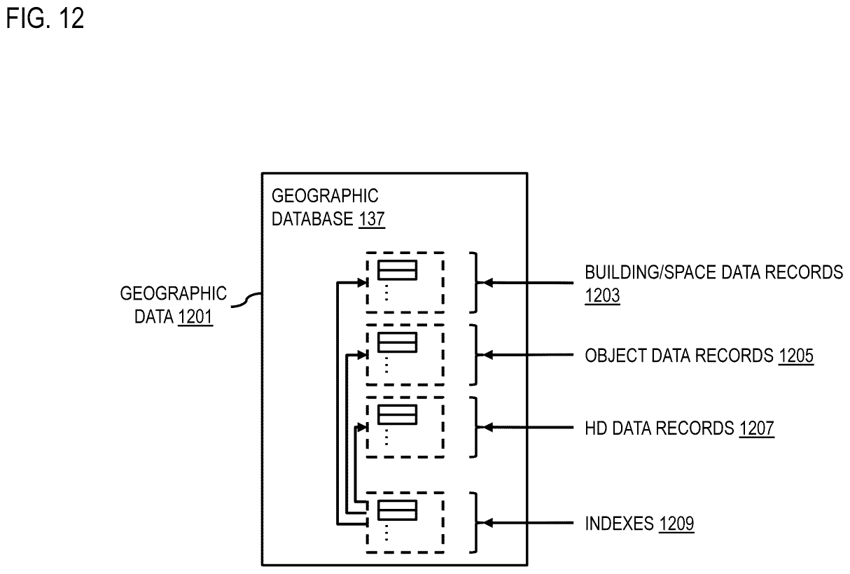

FIG. 12 is a diagram of a geographic database 137, according to one embodiment. In one embodiment, the geographic database 137 includes geographic data 1201 used for (or configured to be compiled to be used for) mapping and/or navigation-related services, such as for providing map embedding analytics according to the embodiments described herein. For example, the map data records stored herein can be used to determine the semantic relationships among the map features, attributes, categories, etc. represented in the geographic data 1201. In one embodiment, the geographic database 137 includes high definition (HD) mapping data that provide centimeter-level or better accuracy of map features. For example, the geographic database 137 can be based on Light Detection and Ranging (LiDAR) or equivalent technology to collect 3D points and model available spaces 103 in which objects may be placed.

In one embodiment, the available spaces 103 (e.g., indoor spaces) and their features (e.g., two-dimensional or three-dimensional features) are represented using polylines and/or polygons (e.g., two-dimensional features) or polygon extrusions (e.g., three-dimensional features). In one embodiment, these polylines/polygons can also represent ground truth or reference the available spaces 103 and/or objects 101 that can be placed therein. For example, the polylines or polygons can correspond to the boundaries or edges of the available spaces 103. In the case of a building, room, etc., a two-dimensional polygon can be used to represent a footprint of the building or available space 103, and a three-dimensional polygon extrusion can be used to represent the three-dimensional surfaces (e.g., including planar surfaces) of the building or available space 103. Accordingly, the terms polygons and polygon extrusions as used herein can be used interchangeably.

In one embodiment, the following terminology applies to the representation of geographic features of an available space 103 and/or object 101 in the geographic database 137.

“Simple polygon”—An interior area of an outer boundary formed by a string of oriented links that begins and ends in one node. In one embodiment, a simple polygon does not cross itself.

“Polygon”—An area bounded by an outer boundary and none or at least one interior boundary (e.g., a hole or island). In one embodiment, a polygon is constructed from one outer simple polygon and none or at least one inner simple polygon. A polygon is simple if it just consists of one simple polygon, or complex if it has at least one inner simple polygon.

In one embodiment, the geographic database 137 follows certain conventions. For example, road links or any other linear geographic features (also referred to herein as links) do not cross themselves and do not cross each other except at a node. Also, there are no duplicated shape points, nodes, or links. Two links that connect to each other have a common node. In the geographic database 137, overlapping geographic features are represented by overlapping polygons. When polygons overlap, the boundary of one polygon crosses the boundary of the other polygon. In the geographic database 137, the location at which the boundary of one polygon intersects they boundary of another polygon is represented by a node. In one embodiment, a node may be used to represent other locations along the boundary of a polygon than a location at which the boundary of the polygon intersects the boundary of another polygon. In one embodiment, a shape point is not used to represent a point at which the boundary of a polygon intersects the boundary of another polygon.

As shown, the geographic database 137 includes building/space data records 1203, object data records 1205, HD data records 1207, and indexes 1209, for example. More, fewer, or different data records can be provided. In one embodiment, additional data records (not shown) can include cartographic (“carto”) data records, routing data, and maneuver data. In one embodiment, the indexes 1209 may improve the speed of data retrieval operations in the geographic database 137. In one embodiment, the indexes 1209 may be used to quickly locate data without having to search every row in the geographic database 137 every time it is accessed. For example, in one embodiment, the indexes 1209 can be a spatial index of the polygon points associated with stored feature polygons. In one or more embodiments, data of a data record may be attributes of another data record.

In one embodiment, the building/space data records 1203 store representations of the footprint or 3D models of buildings and/or other available spaces 103 (e.g., indoor spaces). The building/space data records 1203 can be stored in a central database (e.g., network side) for public records (e.g., available spaces 103 in public buildings, points of interest, etc.) and/or in a local database (e.g., client device side) for private records (e.g., available spaces 103 in private homes or spaces). The building/space data records 1203 can be associated with attributes, such as geographic coordinates, building/space types, physical dimensions, planar surfaces, spatial volumes, positions of objects 101 placed/stored within, etc. The geographic database 137 can include data about the buildings/spaces related to POIs and their respective locations in the building/space data records 1203.

In one embodiment, the geographic database 137 can also include object data records 1209 for storing the object spatial cost 121, available spatial budget 127, object spatial budget 119, geometrical costs 139, other cost data 141, and/or any other related data that is used or generated according to the embodiments described herein. By way of example, the object data records 1209 can be associated with one or more of the node records 1203, road segment records 1205, and/or POI data records 1207 to associate the object data records 1209 with specific places (e.g., indoor places), POIs, geographic areas, and/or other map features. In this way, the object data records 1209 can also be associated with the characteristics or metadata of the corresponding records 1203, 1205, and/or 1207.

In one embodiment, as discussed above, the HD data records 1207 model buildings, available spaces 103, related surfaces, and/or other map features to centimeter-level or better accuracy. The HD data records 1207 also include space and/or object models that provide precise building/space/object geometries with polylines or polygonal boundaries, as well as rich attributes of the models. These rich attributes include, but are not limited to, object type, object location, object placement/orientation, object physical attributes, and/or the like. In one embodiment, the HD data records 1207 are divided into spatial partitions of varying sizes to provide HD mapping data to end user devices with near real-time speed without overloading the available resources of the devices (e.g., computational, memory, bandwidth, etc. resources).

In one embodiment, the HD data records 1207 are created from high-resolution 3D mesh or point-cloud data generated, for instance, from LiDAR sensors/devices-equipped vehicles. The 3D mesh or point-cloud data are processed to create 3D representations of a street or geographic environment at centimeter-level accuracy for storage in the HD data records 1207. The spatial dimensions, volumes, etc. of the available spaces 103 and/or objects 101 can then be retrieved from the geographic database 137.

In one embodiment, the HD data records 1207 also include real-time sensor data collected from probe devices (e.g., UEs 111) in the field. The real-time sensor data, for instance, integrates real-time positioning information with highly detailed 3D representations of buildings and/or available spaces 103 in which the probe devices are traveling to provide precise real-time mobility data or patterns (e.g., including probe data or trajectories) also at centimeter-level accuracy.

In one embodiment, the geographic database 137 can be maintained by the content provider 143 in association with the mapping platform 131 (e.g., a map developer or service provider). The map developer can collect geographic data to generate and enhance the geographic database 137. There can be different ways used by the map developer to collect data. These ways can include obtaining data from other sources, such as building owners, municipalities, or respective geographic authorities. In addition, the map developer can employ field personnel to survey buildings and/or available spaces 103 throughout a geographic region to observe features and/or record information about them, for example. Also, remote sensing, such as aerial or satellite photography, can be used.

The geographic database 137 can be a master geographic database stored in a format that facilitates updating, maintenance, and development. For example, the master geographic database or data in the master geographic database can be in an Oracle spatial format or other format (e.g., capable of accommodating multiple/different map layers), such as for development or production purposes. The Oracle spatial format or development/production database can be compiled into a delivery format, such as a geographic data files (GDF) format. The data in the production and/or delivery formats can be compiled or further compiled to form geographic database products or databases, which can be used in end user navigation devices or systems.

The processes described herein for determining object utility for personalizing services for space utilization may be advantageously implemented via software, hardware (e.g., general processor, Digital Signal Processing (DSP) chip, an Application Specific Integrated Circuit (ASIC), Field Programmable Gate Arrays (FPGAs), etc.), firmware or a combination thereof. Such exemplary hardware for performing the described functions is detailed below.

Additionally, as used herein, the term ‘circuitry’ may refer to (a) hardware-only circuit implementations (for example, implementations in analog circuitry and/or digital circuitry); (b) combinations of circuits and computer program product(s) comprising software and/or firmware instructions stored on one or more computer readable memories that work together to cause an apparatus to perform one or more functions described herein; and (c) circuits, such as, for example, a microprocessor(s) or a portion of a microprocessor(s), that require software or firmware for operation even if the software or firmware is not physically present. This definition of ‘circuitry’ applies to all uses of this term herein, including in any claims. As a further example, as used herein, the term ‘circuitry’ also includes an implementation comprising one or more processors and/or portion(s) thereof and accompanying software and/or firmware. As another example, the term ‘circuitry’ as used herein also includes, for example, a baseband integrated circuit or applications processor integrated circuit for a mobile phone or a similar integrated circuit in a server, a cellular device, other network device, and/or other computing device.

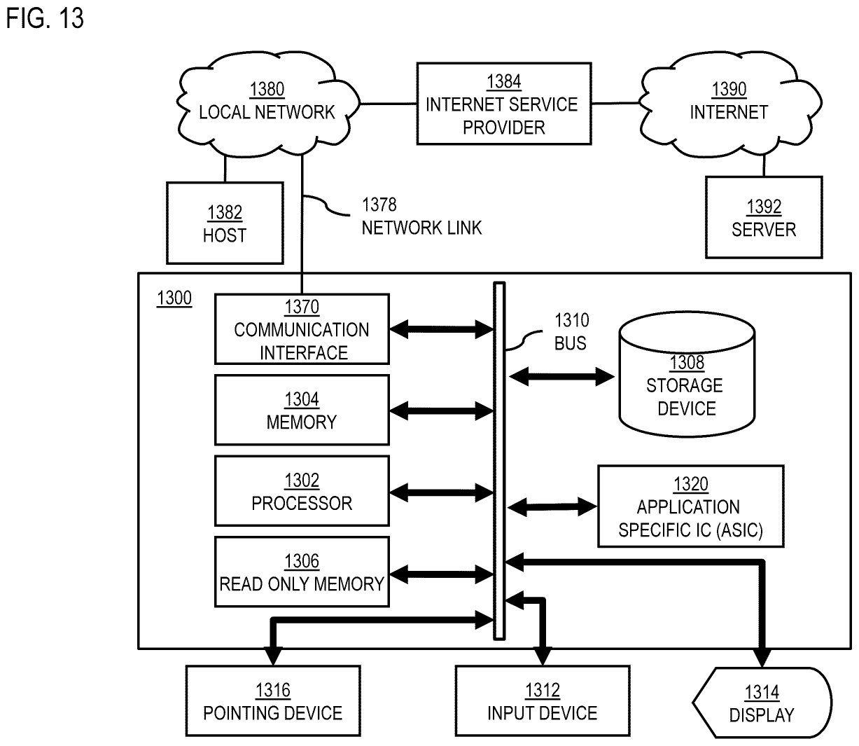

FIG. 13 illustrates a computer system 1300 upon which an embodiment of the invention may be implemented. Computer system 1300 is programmed (e.g., via computer program code or instructions) to determine object utility for personalizing services for space utilization as described herein and includes a communication mechanism such as a bus 1310 for passing information between other internal and external components of the computer system 1300. Information (also called data) is represented as a physical expression of a measurable phenomenon, typically electric voltages, but including, in other embodiments, such phenomena as magnetic, electromagnetic, pressure, chemical, biological, molecular, atomic, sub-atomic and quantum interactions. For example, north and south magnetic fields, or a zero and non-zero electric voltage, represent two states (0, 1) of a binary digit (bit). Other phenomena can represent digits of a higher base. A superposition of multiple simultaneous quantum states before measurement represents a quantum bit (qubit). A sequence of one or more digits constitutes digital data that is used to represent a number or code for a character. In some embodiments, information called analog data is represented by a near continuum of measurable values within a particular range.

A bus 1310 includes one or more parallel conductors of information so that information is transferred quickly among devices coupled to the bus 1310. One or more processors 1302 for processing information are coupled with the bus 1310.

A processor 1302 performs a set of operations on information as specified by computer program code related to determining object utility for personalizing services for space utilization. The computer program code is a set of instructions or statements providing instructions for the operation of the processor and/or the computer system to perform specified functions. The code, for example, may be written in a computer programming language that is compiled into a native instruction set of the processor. The code may also be written directly using the native instruction set (e.g., machine language). The set of operations include bringing information in from the bus 1310 and placing information on the bus 1310. The set of operations also typically include comparing two or more units of information, shifting positions of units of information, and combining two or more units of information, such as by addition or multiplication or logical operations like OR, exclusive OR (XOR), and AND. Each operation of the set of operations that can be performed by the processor is represented to the processor by information called instructions, such as an operation code of one or more digits. A sequence of operations to be executed by the processor 1302, such as a sequence of operation codes, constitute processor instructions, also called computer system instructions or, simply, computer instructions. Processors may be implemented as mechanical, electrical, magnetic, optical, chemical or quantum components, among others, alone or in combination.

Computer system 1300 also includes a memory 1304 coupled to bus 1310. The memory 1304, such as a random access memory (RAM) or other dynamic storage device, stores information including processor instructions for determining object utility for personalizing services for space utilization. Dynamic memory allows information stored therein to be changed by the computer system 1300. RAM allows a unit of information stored at a location called a memory address to be stored and retrieved independently of information at neighboring addresses. The memory 1304 is also used by the processor 1302 to store temporary values during execution of processor instructions. The computer system 1300 also includes a read only memory (ROM) 1306 or other static storage device coupled to the bus 1310 for storing static information, including instructions, that is not changed by the computer system 1300. Some memory is composed of volatile storage that loses the information stored thereon when power is lost. Also coupled to bus 1310 is a non-volatile (persistent) storage device 1308, such as a magnetic disk, optical disk or flash card, for storing information, including instructions, that persists even when the computer system 1300 is turned off or otherwise loses power.

Information, including instructions for determining object utility for personalizing services for space utilization, is provided to the bus 1310 for use by the processor from an external input device 1312, such as a keyboard containing alphanumeric keys operated by a human user, or a sensor. A sensor detects conditions in its vicinity and transforms those detections into physical expressions compatible with the measurable phenomenon used to represent information in computer system 1300. Other external devices coupled to bus 1310, used primarily for interacting with humans, include a display device 1314, such as a cathode ray tube (CRT) or a liquid crystal display (LCD), or plasma screen or printer for presenting text or images, and a pointing device 1316, such as a mouse or a trackball or cursor direction keys, or motion sensor, for controlling a position of a small cursor image presented on the display 1314 and issuing commands associated with graphical elements presented on the display 1314. In some embodiments, for example, in embodiments in which the computer system 1300 performs all functions automatically without human input, one or more of external input device 1312, display device 1314 and pointing device 1316 is omitted.

In the illustrated embodiment, special purpose hardware, such as an application specific integrated circuit (ASIC) 1320, is coupled to bus 1310. The special purpose hardware is configured to perform operations not performed by processor 1302 quickly enough for special purposes. Examples of application specific ICs include graphics accelerator cards for generating images for display 1314, cryptographic boards for encrypting and decrypting messages sent over a network, speech recognition, and interfaces to special external devices, such as robotic arms and medical scanning equipment that repeatedly perform some complex sequence of operations that are more efficiently implemented in hardware.

Computer system 1300 also includes one or more instances of a communications interface 1370 coupled to bus 1310. Communication interface 1370 provides a one-way or two-way communication coupling to a variety of external devices that operate with their own processors, such as printers, scanners and external disks. In general, the coupling is with a network link 1378 that is connected to a local network 1380 to which a variety of external devices with their own processors are connected. For example, communication interface 1370 may be a parallel port or a serial port or a universal serial bus (USB) port on a personal computer. In some embodiments, communications interface 1370 is an integrated services digital network (ISDN) card or a digital subscriber line (DSL) card or a telephone modem that provides an information communication connection to a corresponding type of telephone line. In some embodiments, a communication interface 1370 is a cable modem that converts signals on bus 1310 into signals for a communication connection over a coaxial cable or into optical signals for a communication connection over a fiber optic cable. As another example, communications interface 1370 may be a local area network (LAN) card to provide a data communication connection to a compatible LAN, such as Ethernet. Wireless links may also be implemented. For wireless links, the communications interface 1370 sends or receives or both sends and receives electrical, acoustic or electromagnetic signals, including infrared and optical signals, that carry information streams, such as digital data. For example, in wireless handheld devices, such as mobile telephones like cell phones, the communications interface 1370 includes a radio band electromagnetic transmitter and receiver called a radio transceiver. In certain embodiments, the communications interface 1370 enables connection to the communication network 133 for determining object utility for personalizing services for space utilization.

The term computer-readable medium is used herein to refer to any medium that participates in providing information to processor 1302, including instructions for execution. Such a medium may take many forms, including, but not limited to, non-volatile media, volatile media and transmission media. Non-volatile media include, for example, optical or magnetic disks, such as storage device 1308. Volatile media include, for example, dynamic memory 1304. Transmission media include, for example, coaxial cables, copper wire, fiber optic cables, and carrier waves that travel through space without wires or cables, such as acoustic waves and electromagnetic waves, including radio, optical and infrared waves. Signals include man-made transient variations in amplitude, frequency, phase, polarization or other physical properties transmitted through the transmission media. Common forms of computer-readable media include, for example, a floppy disk, a flexible disk, hard disk, magnetic tape, any other magnetic medium, a CD-ROM, CDRW, DVD, any other optical medium, punch cards, paper tape, optical mark sheets, any other physical medium with patterns of holes or other optically recognizable indicia, a RAM, a PROM, an EPROM, a FLASH-EPROM, any other memory chip or cartridge, a carrier wave, or any other medium from which a computer can read.

Network link 1378 typically provides information communication using transmission media through one or more networks to other devices that use or process the information. For example, network link 1378 may provide a connection through local network 1380 to a host computer 1382 or to equipment 1384 operated by an Internet Service Provider (ISP). ISP equipment 1384 in turn provides data communication services through the public, world-wide packet-switching communication network of networks now commonly referred to as the Internet 1390.

A computer called a server host 1392 connected to the Internet hosts a process that provides a service in response to information received over the Internet. For example, server host 1392 hosts a process that provides information representing video data for presentation at display 1314. It is contemplated that the components of the system can be deployed in various configurations within other computer systems, e.g., host 1382 and server 1392.

FIG. 14 illustrates a chip set 1400 upon which an embodiment of the invention may be implemented. Chip set 1400 is programmed to determine object utility for personalizing services for space utilization as described herein and includes, for instance, the processor and memory components described with respect to FIG. 13 incorporated in one or more physical packages (e.g., chips). By way of example, a physical package includes an arrangement of one or more materials, components, and/or wires on a structural assembly (e.g., a baseboard) to provide one or more characteristics such as physical strength, conservation of size, and/or limitation of electrical interaction. It is contemplated that in certain embodiments the chip set can be implemented in a single chip.

In one embodiment, the chip set 1400 includes a communication mechanism such as a bus 1401 for passing information among the components of the chip set 1400. A processor 1403 has connectivity to the bus 1401 to execute instructions and process information stored in, for example, a memory 1405. The processor 1403 may include one or more processing cores with each core configured to perform independently. A multi-core processor enables multiprocessing within a single physical package. Examples of a multi-core processor include two, four, eight, or greater numbers of processing cores. Alternatively or in addition, the processor 1403 may include one or more microprocessors configured in tandem via the bus 1401 to enable independent execution of instructions, pipelining, and multithreading. The processor 1403 may also be accompanied with one or more specialized components to perform certain processing functions and tasks such as one or more digital signal processors (DSP) 1407, or one or more application-specific integrated circuits (ASIC) 1409. A DSP 1407 typically is configured to process real-world signals (e.g., sound) in real time independently of the processor 1403. Similarly, an ASIC 1409 can be configured to perform specialized functions not easily performed by a general purposed processor. Other specialized components to aid in performing the inventive functions described herein include one or more field programmable gate arrays (FPGA) (not shown), one or more controllers (not shown), or one or more other special-purpose computer chips.

The processor 1403 and accompanying components have connectivity to the memory 1405 via the bus 1401. The memory 1405 includes both dynamic memory (e.g., RAM, magnetic disk, writable optical disk, etc.) and static memory (e.g., ROM, CD-ROM, etc.) for storing executable instructions that when executed perform the inventive steps described herein to determine object utility for personalizing services for space utilization. The memory 1405 also stores the data associated with or generated by the execution of the inventive steps.

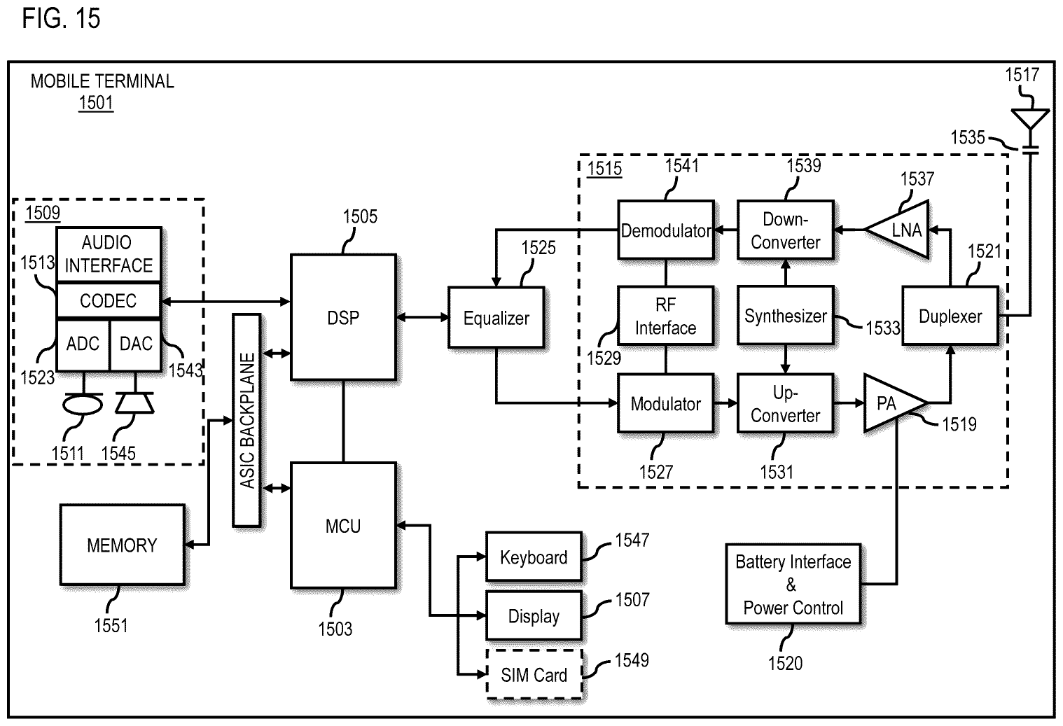

FIG. 15 is a diagram of exemplary components of a mobile terminal (e.g., UE 111 or component thereof) capable of operating in the system of FIG. 1, according to one embodiment. Generally, a radio receiver is often defined in terms of front-end and back-end characteristics. The front-end of the receiver encompasses all of the Radio Frequency (RF) circuitry whereas the back-end encompasses all of the base-band processing circuitry. Pertinent internal components of the telephone include a Main Control Unit (MCU) 1503, a Digital Signal Processor (DSP) 1505, and a receiver/transmitter unit including a microphone gain control unit and a speaker gain control unit. A main display unit 1507 provides a display to the user in support of various applications and mobile station functions that offer automatic contact matching. An audio function circuitry 1509 includes a microphone 1511 and microphone amplifier that amplifies the speech signal output from the microphone 1511. The amplified speech signal output from the microphone 1511 is fed to a coder/decoder (CODEC) 1513.

A radio section 1515 amplifies power and converts frequency in order to communicate with a base station, which is included in a mobile communication system, via antenna 1517. The power amplifier (PA) 1519 and the transmitter/modulation circuitry are operationally responsive to the MCU 1503, with an output from the PA 1519 coupled to the duplexer 1521 or circulator or antenna switch, as known in the art. The PA 1519 also couples to a battery interface and power control unit 1520.

In use, a user of mobile station 1501 speaks into the microphone 1511 and his or her voice along with any detected background noise is converted into an analog voltage. The analog voltage is then converted into a digital signal through the Analog to Digital Converter (ADC) 1523. The control unit 1503 routes the digital signal into the DSP 1505 for processing therein, such as speech encoding, channel encoding, encrypting, and interleaving. In one embodiment, the processed voice signals are encoded, by units not separately shown, using a cellular transmission protocol such as global evolution (EDGE), general packet radio service (GPRS), global system for mobile communications (GSM), Internet protocol multimedia subsystem (IMS), universal mobile telecommunications system (UMTS), etc., as well as any other suitable wireless medium, e.g., microwave access (WiMAX), Long Term Evolution (LTE) networks, 5G New Radio networks, code division multiple access (CDMA), wireless fidelity (WiFi), satellite, and the like.

The encoded signals are then routed to an equalizer 1525 for compensation of any frequency-dependent impairments that occur during transmission though the air such as phase and amplitude distortion. After equalizing the bit stream, the modulator 1527 combines the signal with an RF signal generated in the RF interface 1529. The modulator 1527 generates a sine wave by way of frequency or phase modulation. In order to prepare the signal for transmission, an up-converter 1531 combines the sine wave output from the modulator 1527 with another sine wave generated by a synthesizer 1533 to achieve the desired frequency of transmission. The signal is then sent through a PA 1519 to increase the signal to an appropriate power level. In practical systems, the PA 1519 acts as a variable gain amplifier whose gain is controlled by the DSP 1505 from information received from a network base station. The signal is then filtered within the duplexer 1521 and optionally sent to an antenna coupler 1535 to match impedances to provide maximum power transfer. Finally, the signal is transmitted via antenna 1517 to a local base station. An automatic gain control (AGC) can be supplied to control the gain of the final stages of the receiver. The signals may be forwarded from there to a remote telephone which may be another cellular telephone, other mobile phone or a landline connected to a Public Switched Telephone Network (PSTN), or other telephony networks.

Voice signals transmitted to the mobile station 1501 are received via antenna 1517 and immediately amplified by a low noise amplifier (LNA) 1537. A down-converter 1539 lowers the carrier frequency while the demodulator 1541 strips away the RF leaving only a digital bit stream. The signal then goes through the equalizer 1525 and is processed by the DSP 1505. A Digital to Analog Converter (DAC) 1543 converts the signal and the resulting output is transmitted to the user through the speaker 1545, all under control of a Main Control Unit (MCU) 1503—which can be implemented as a Central Processing Unit (CPU) (not shown).

The MCU 1503 receives various signals including input signals from the keyboard 1547. The keyboard 1547 and/or the MCU 1503 in combination with other user input components (e.g., the microphone 1511) comprise a user interface circuitry for managing user input. The MCU 1503 runs a user interface software to facilitate user control of at least some functions of the mobile station 1501 to determine object utility for personalizing services for space utilization. The MCU 1503 also delivers a display command and a switch command to the display 1507 and to the speech output switching controller, respectively. Further, the MCU 1503 exchanges information with the DSP 1505 and can access an optionally incorporated SIM card 1549 and a memory 1551. In addition, the MCU 1503 executes various control functions required of the station. The DSP 1505 may, depending upon the implementation, perform any of a variety of conventional digital processing functions on the voice signals. Additionally, DSP 1505 determines the background noise level of the local environment from the signals detected by microphone 1511 and sets the gain of microphone 1511 to a level selected to compensate for the natural tendency of the user of the mobile station 1501.

The CODEC 1513 includes the ADC 1523 and DAC 1543. The memory 1551 stores various data including call incoming tone data and is capable of storing other data including music data received via, e.g., the global Internet. The software module could reside in RAM memory, flash memory, registers, or any other form of writable computer-readable storage medium known in the art including non-transitory computer-readable storage medium. For example, the memory device 1551 may be, but not limited to, a single memory, CD, DVD, ROM, RAM, EEPROM, optical storage, or any other non-volatile or non-transitory storage medium capable of storing digital data.

An optionally incorporated SIM card 1549 carries, for instance, important information, such as the cellular phone number, the carrier supplying service, subscription details, and security information. The SIM card 1549 serves primarily to identify the mobile station 1501 on a radio network. The card 1549 also contains a memory for storing a personal telephone number registry, text messages, and user specific mobile station settings.

While the invention has been described in connection with a number of embodiments and implementations, the invention is not so limited but covers various obvious modifications and equivalent arrangements, which fall within the purview of the appended claims. Although features of the invention are expressed in certain combinations among the claims, it is contemplated that these features can be arranged in any combination and order.

What is claimed is:

1. A method comprising:
using a sensor to capture sensor data of an environment including an object over a period of time;
processing the sensor data to track one or more interactions between at least one user and the object over the period of time;
determining a utility value of the object based on the one or more interactions; and
providing the utility value as an output.

2. The method of claim 1, further comprising:
determining a service, an action, or a combination thereof to apply to the object based on the utility value.

3. The method of claim 2, further comprising:
determining a spatial budget of the object within the environment,
wherein the service, the action, or the combination thereof is determined further based on the spatial budget.

4. The method of claim 2, further comprising:
initiating the service, the action, or a combination thereof based on determining that the utility value is below a threshold value.

5. The method of claim 2, wherein the service, the action, or a combination thereof relates to a removal of the object from the environment.

6. The method of claim 2, wherein the service is a storage service, and wherein the action comprises initiating a reservation at a storage service to facilitate a storage of the object.

7. The method of claim 2, wherein the service is an auction or marketplace service, and wherein the action comprises generating a listing on the service to sell or give away the object.

8. The method of claim 2, wherein the service is a rental service, and wherein the action comprises generating a listing on the service to rent the object to another user.

9. The method of claim 2, wherein the determining of the utility value comprises determining a context associated with the utility value; and wherein the service, the action, or a combination thereof is determined based on the context.

10. The method of claim 1, wherein the action includes a decluttering of the environment, a hiding of the object, a displaying of the object, a moving of the object, or a combination thereof.

11. The method of claim 1, wherein the context includes a temporal context, a weather context, a user emotional state, or a combination thereof.

12. The method of claim 1, further comprising:
determining a recommended placement of the object within the environment based on the utility value.

13. The method of claim 1, wherein the utility value is determined using a trained machine learning model based on one or more attributes of the object, the one or more interactions, the environment, an associated context, or a combination thereof.

14. The method of claim 1, wherein the utility value is determined based on a relative utility ranking of the object in relation to one or more other objects.

15. An apparatus comprising:
at least one processor; and
at least one memory including computer program code for one or more programs,
the at least one memory and the computer program code configured to, with the at least one processor, cause the apparatus to perform at least the following,
use a sensor to capture sensor data of an environment including an object over a period of time;
process the sensor data to track one or more interactions between at least one user and the object over the period of time;
determine a utility value of the object based on the one or more interactions; and
provide the utility value as an output.

16. The apparatus of claim 15, wherein the apparatus is further caused to:
determine a service, an action, or a combination thereof to apply to the object based on the utility value.

17. The apparatus of claim 16, wherein the apparatus is further caused to:
determine a spatial budget of the object within the environment,
wherein the service, the action, or the combination thereof is determined further based on the spatial budget.

18. A non-transitory computer-readable storage medium carrying one or more sequences of one or more instructions which, when executed by one or more processors, cause an apparatus to perform:
using a sensor to capture sensor data of an environment including an object over a period of time;
processing the sensor data to track one or more interactions between at least one user and the object over the period of time;
determining a utility value of the object based on the one or more interactions; and
providing the utility value as an output.

19. The non-transitory computer-readable storage medium of claim 1, wherein the apparatus is caused to further perform:
determining a service, an action, or a combination thereof to apply to the object based on the utility value.

20. The non-transitory computer-readable storage medium of claim 2, wherein the apparatus is caused to further perform:
determining a spatial budget of the object within the environment,
wherein the service, the action, or the combination thereof is determined further based on the spatial budget.
